(19) United States
(12) Patent Application Publication
(10) Pub. No.: US 2026/0007016 A1
(43) Pub. Date: Jan. 1, 2026

(54) DISPLAY DEVICE AND METHOD OF MANUFACTURING THE SAME

(71) Applicant: Samsung Display Co., LTD., Yongin-si (KR)

(72) Inventors: Chan Hyun PARK, Yongin-si (KR); Min Seok KIM, Yongin-si (KR); Gwang Geun LEE, Yongin-si (KR); Won Ho JANG, Yongin-si (KR); Ki Hoon HA, Yongin-si (KR)

(73) Assignee: Samsung Display Co., LTD., Yongin-si (KR)

(21) Appl. No.: 19/172,915

(22) Filed: Apr. 8, 2025

(30) Foreign Application Priority Data
Jun. 28, 2024 (KR) 10-2024-0085561

(51) Int. Cl. H10K 59/131; H10H 29/01; H10H 29/49; H10K 59/12

(52) U.S. Cl. CPC H10K 59/131; H10H 29/012; H10H 29/49; H10K 59/1201

(57) ABSTRACT

Provided is a display including a substrate, a light emitting element disposed on an upper surface of the substrate in a display area, an upper conductive line disposed on the upper surface of the substrate in a non-display area around the display area and having first openings, an upper pad electrode disposed on the upper conductive line, a first insulating layer disposed on the upper pad electrode and exposing a portion of the upper pad electrode, a lower conductive line disposed on a lower surface of the substrate in the non-display area, and a side surface connection line disposed on a side surface of the substrate, electrically connecting the exposed portion of the upper pad electrode to the lower conductive line, and overlapping the first openings. The upper pad electrode has first grooves overlapping the first openings in a thickness direction.

### CROSS-REFERENCE TO RELATED APPLICATION(S)

This application claims priority to and benefits of Korean Patent Application No. 10-2024-0085561 under 35 U.S.C. § 119, filed on Jun. 28, 2024, in the Korean Intellectual Property Office, the entire contents of which are incorporated herein by reference.

### BACKGROUND

### 1. Technical Field

The disclosure relates to an electronic device, and more particularly to a display device and a method of manufacturing the display device.

### 2. Description of the Related Art

Recently, as interest in an information display is increased, research and development on a display device is continuously being conducted.

The display device is manufactured through multiple process steps. In a manufacturing process, relatively more stress may be applied to a side surface of a display panel compared to other parts, and a defect may occur in a configuration disposed on the side surface of the display panel due to the stress.

The content described above is only intended to help understanding of the background technology of the technical ideas of the disclosure, and therefore, it cannot be understood as content corresponding to prior art known to those skilled in the art of the disclosure.

### SUMMARY

Embodiments of the disclosure are to provide a display panel with improved reliability. For example, a side surface connection line of a display panel may be prevented from being lost or deformed due to stress in a manufacturing process.

According to an embodiment of the disclosure, a display device may include a substrate having an upper surface, a lower surface opposite to the upper surface, and a side surface connecting the upper surface and the lower surface, a light emitting element disposed on the upper surface of the substrate in a display area, an upper conductive line disposed on the upper surface of the substrate in a non-display area around the display area and having first openings, an upper pad electrode disposed on the upper conductive line, a first insulating layer disposed on the upper pad electrode and exposing a portion of the upper pad electrode, a lower conductive line disposed on the lower surface of the substrate in the non-display area, and a side surface connection line disposed on the side surface of the substrate, electrically connecting the exposed portion of the upper pad electrode to the lower conductive line, and overlapping the first openings. The upper pad electrode has first grooves overlapping the first openings in a thickness direction.

The first insulating layer may have second grooves overlapping a portion of the first grooves.

In a plan view, the first grooves may have substantially the same shape as the first openings, and the second grooves may have substantially the same shape as the portion of the first grooves.

The upper pad electrode may be disposed on the upper conductive line and may be in direct contact with the upper conductive line, and the first insulating layer may be directly disposed on the upper pad electrode and may be in direct contact with the upper pad electrode.

The first openings may include one or more holes adjacent to each other and one or more slits adjacent to each other, and the first insulating layer may overlap the one or more holes without overlapping the one or more slits.

The non-display area may be adjacent to the display area in a first direction, and the one or more slits may extend in a second direction crossing the first direction.

In a plan view, each of the one or more holes may have a circular shape, and each of the one or more slits may have a stripe shape.

The one or more holes may be disposed between the one or more slits and the display area.

The display device may further include a second insulating layer disposed on the upper surface of the substrate in the display area and the non-display area, in the non-display area, the upper conductive line may be disposed on the second insulating layer, and in the display area, the light emitting element may be disposed on the second insulating layer.

The display device may further include a lower pad electrode disposed on the lower conductive line, and a second insulating layer disposed on the lower pad electrode and exposing a portion of the lower pad electrode. The side surface connection line may be electrically connected to the exposed portion of the upper pad electrode and the exposed portion of the lower pad electrode.

The lower conductive line may have second openings, and the side surface connection line may overlap the second openings.

The lower pad electrode may have second grooves overlapping the second openings, and the second insulating layer may have third grooves overlapping a portion of the second grooves.

The lower pad electrode may be disposed on the lower conductive line and may be in direct contact with the lower conductive line, and the second insulating layer may be disposed on the lower pad electrode and may be in direct contact with the lower pad electrode.

The second openings may overlap the first openings.

Another aspect of the disclosure relates to a method of manufacturing a display device. The method may include forming a metal layer on an upper surface of a substrate in a non-display area around a display area, forming an upper conductive line having first openings by removing portions of the metal layer, forming an upper pad electrode on the upper conductive line, forming a first insulating layer exposing a portion of the upper pad electrode, on the upper pad electrode, forming a lower conductive line on a lower surface opposite to the upper surface of the substrate in the non-display area, and forming a side surface connection line on a side surface connecting the upper surface and the lower surface of the substrate to electrically connect the exposed portion of the upper pad electrode to the lower conductive line. The upper pad electrode has first grooves overlapping the first openings.

The first insulating layer may have second grooves overlapping a portion of the first grooves.

The method may further include forming a lower pad electrode on the lower conductive line, and forming a second insulating layer exposing a portion of the lower pad electrode, on the lower pad electrode. The side surface connection line may be electrically connected to the exposed portion of the upper pad electrode and the exposed portion of the lower pad electrode.

The lower conductive line may have second openings, the lower pad electrode may have second grooves overlapping the second openings, and the second insulating layer may have third grooves overlapping a portion of the second grooves.

According to an embodiment of the disclosure, an electronic device may include a display device to display images based on image data. The display device includes: a substrate having an upper surface, a lower surface opposite to the upper surface, and a side surface connecting the upper surface and the lower surface; a light emitting element disposed on the upper surface of the substrate in a display area; an upper conductive line disposed on the upper surface of the substrate in a non-display area around the display area and having first openings; an upper pad electrode disposed on the upper conductive line; a first insulating layer disposed on the upper pad electrode and exposing a portion of the upper pad electrode; a lower conductive line disposed on the lower surface of the substrate in the non-display area; and a side surface connection line disposed on the side surface of the substrate, electrically connecting the exposed portion of the upper pad electrode to the lower conductive line, and overlapping the first openings. The upper pad electrode has first grooves overlapping the first openings in a thickness direction.

The electronic device may be at least one of a smart watch, a mobile phone, a smartphone, a portable computer, a tablet personal computer (PC), a watch phone, an automotive display, a smart glass, a portable multimedia player (PMP), a navigation system, an ultra-mobile computer (UMPC), a head mounted display (HMD) device, a virtual reality (VR) device, a mixed reality (MR) device, and an augmented reality (AR) device.

According to embodiments of the disclosure, a display panel with improved reliability may be provided.

An effect according to embodiments is not limited to the content exemplified above, and further various effects are included in the present specification.

### BRIEF DESCRIPTION OF THE DRAWINGS

The above and other features of the disclosure will become more apparent by describing in further detail embodiments thereof with reference to the accompanying drawings, in which:

FIG. 1 is a schematic perspective view illustrating a display device according to an embodiment of the disclosure.

FIG. 2 is an enlarged schematic perspective view illustrating configurations of a display panel in an area A of FIG. 1.

FIG. 3 is a schematic block diagram illustrating an embodiment of the display device of FIG. 1.

FIG. 4 is a schematic block diagram illustrating an embodiment of one of sub-pixels of FIG. 3.

FIG. 5 is a schematic plan view illustrating an embodiment of the display panel of FIG. 1.

FIG. 6 is a schematic cross-sectional view illustrating an embodiment of the display panel of FIG. 5.

FIG. 7 is a schematic plan view illustrating an embodiment of the pixel of FIG. 5.

FIG. 8 is a schematic cross-sectional view taken along line I-I′ of FIG. 7.

FIG. 9 is an enlarged schematic plan view illustrating an area B of FIG. 5.

FIG. 10 is a schematic cross-sectional view taken along line II-II′ of FIG. 9 according to an embodiment of the disclosure.

FIG. 11 is a schematic cross-sectional view taken along line II-II′ of

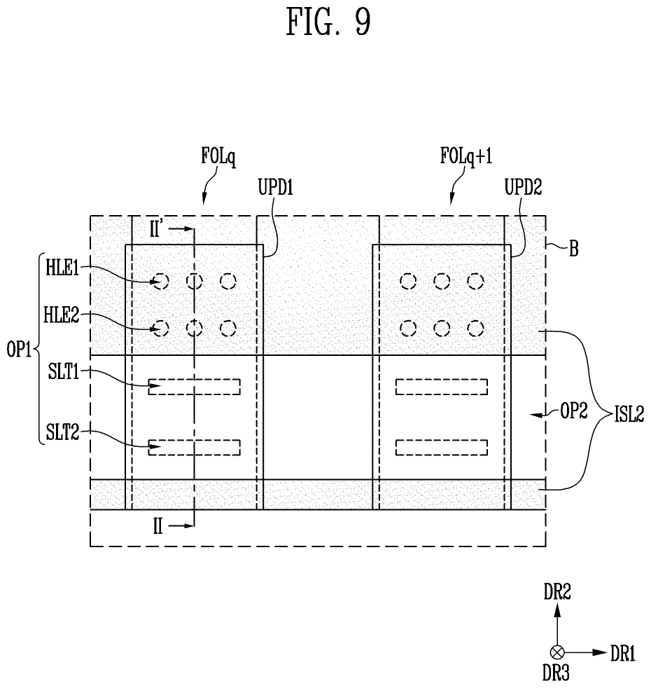

FIG. 9 according to another embodiment of the disclosure.

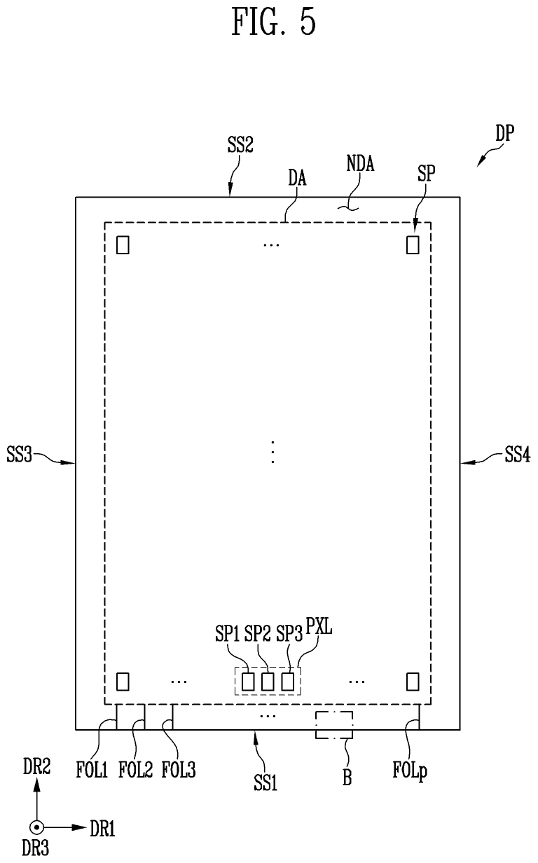

FIG. 12 is an enlarged schematic plan view of the area B of a lower surface of the display panel of FIG. 5 viewed in a third direction.

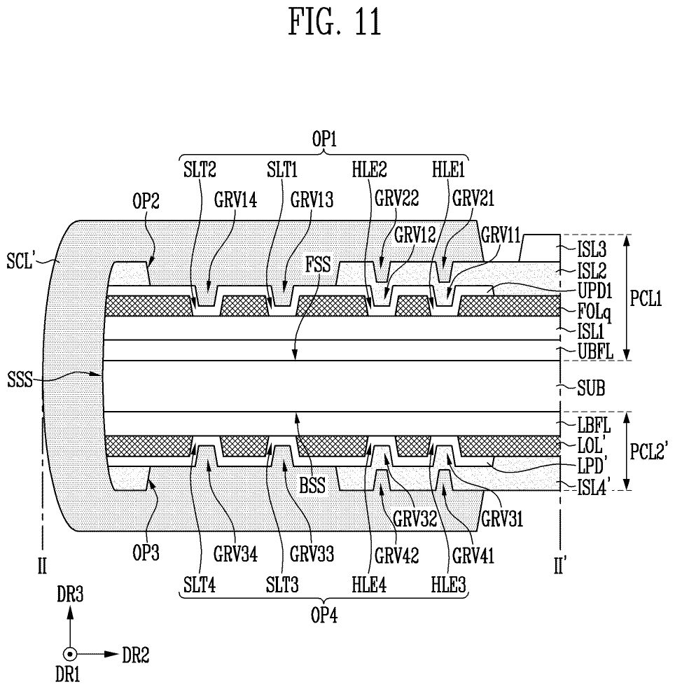

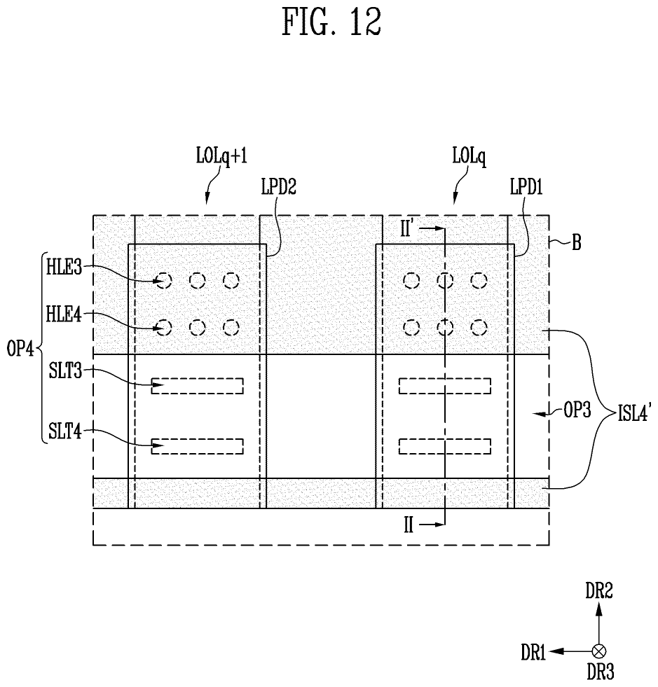

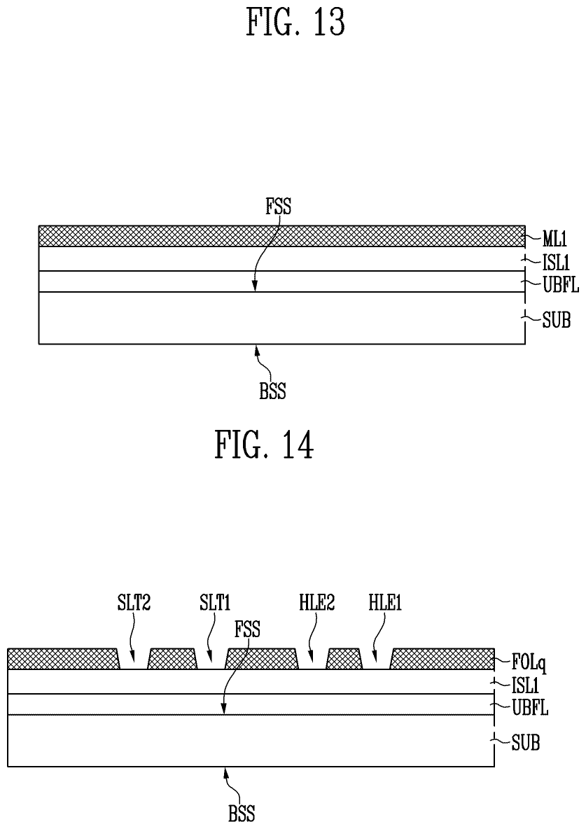

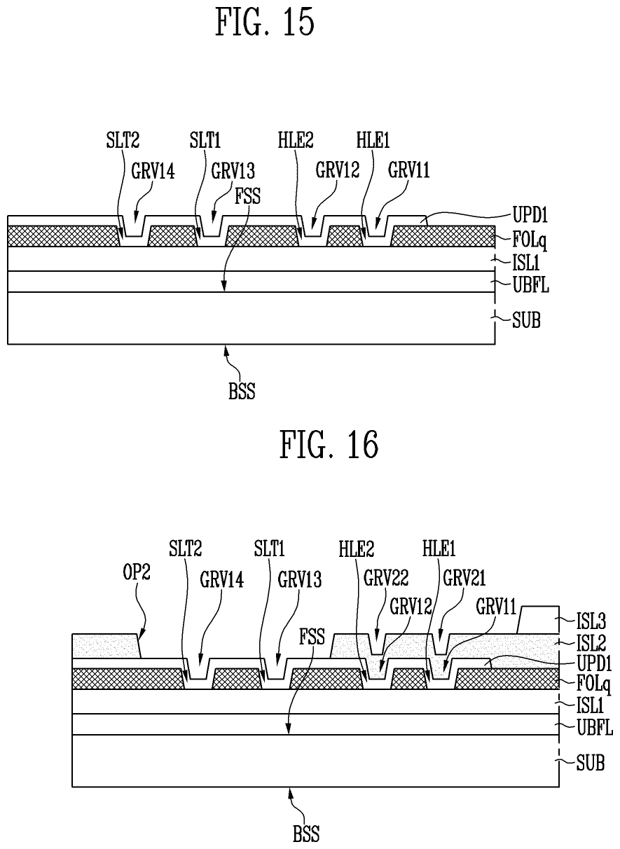

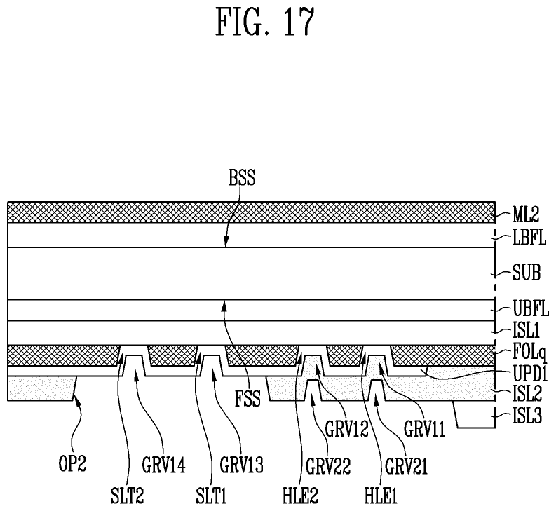

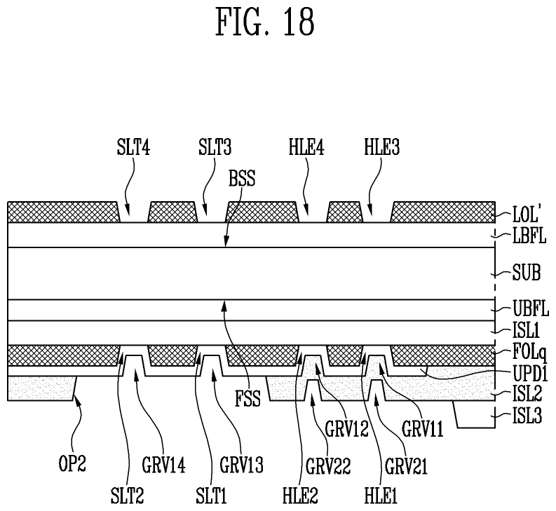

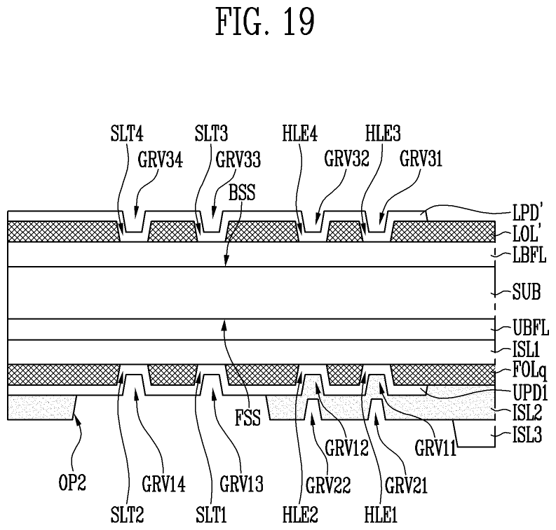

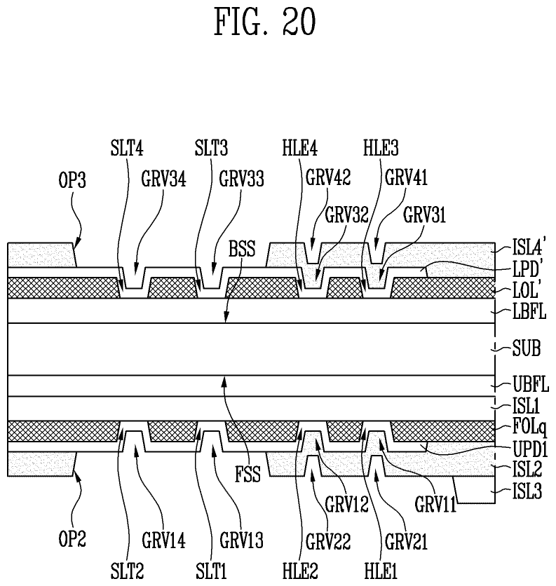

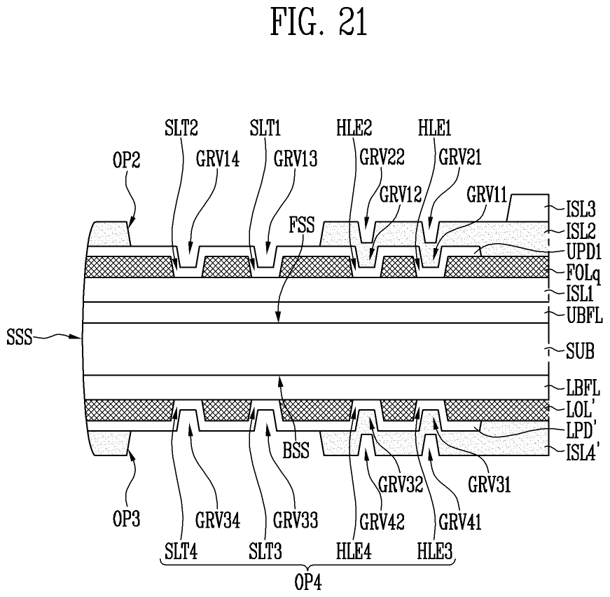

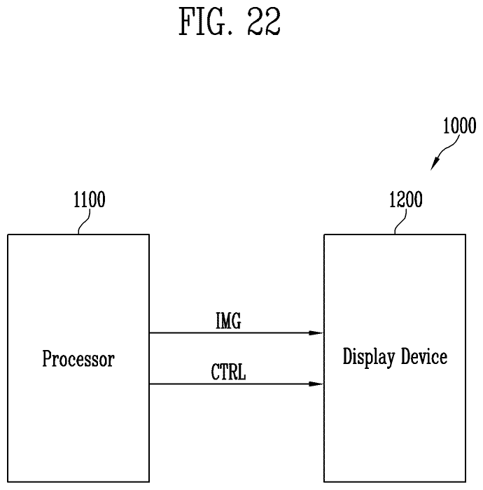

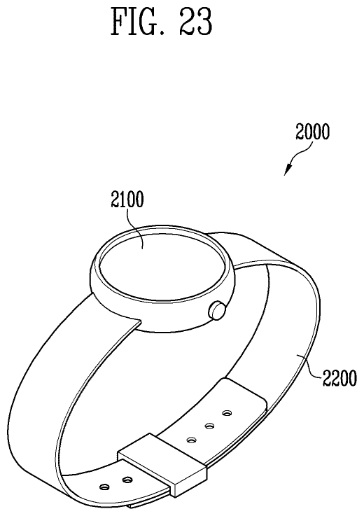

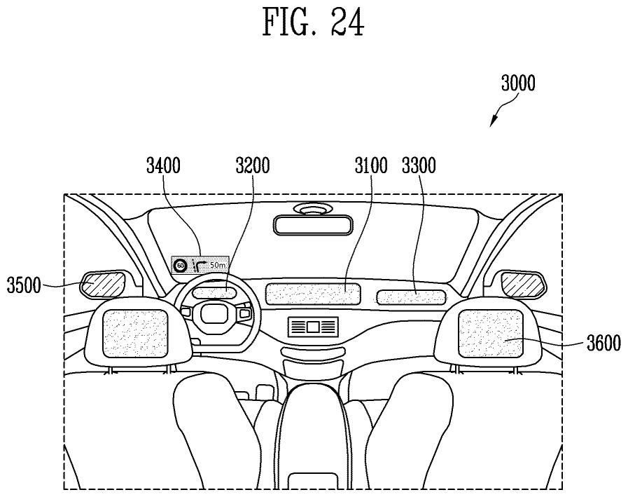

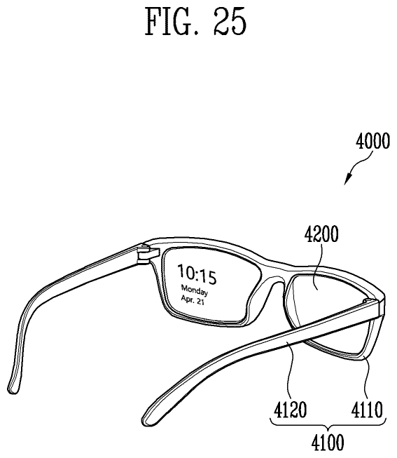

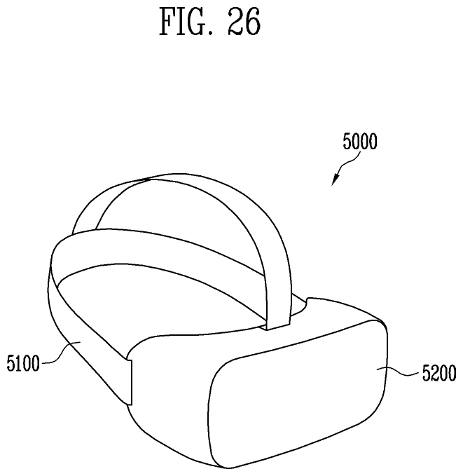

FIGS. 13 to 21 are schematic cross-sectional views illustrating a method of manufacturing a display panel according to the embodiment of FIG. 11.

FIG. 22 is a schematic block diagram illustrating an embodiment of a display system.

FIGS. 23 to 26 are schematic perspective views illustrating application examples of the display system of FIG. 22.

### DETAILED DESCRIPTION OF THE EMBODIMENTS

Hereinafter, a preferred embodiment according to the disclosure is described in detail with reference to the accompanying drawings. It should be noted that in the following description, only portions necessary for understanding an operation according to the disclosure are described, and descriptions of other portions are omitted in order not to obscure the subject matter of the disclosure. The disclosure may be embodied in other forms without being limited to the embodiment described herein. However, the embodiment described herein is provided to describe in detail enough to easily implement the technical spirit of the disclosure to those skilled in the art to which the disclosure belongs.

Throughout the specification, in a case where a portion is “connected” to another portion, the case includes not only a case where the portion is “directly connected” but also a case where the portion is “indirectly connected” with another element interposed therebetween. Terms used herein are for describing specific embodiments and are not intended to limit the disclosure. Throughout the specification, in a case where a certain portion “includes”, the case means that the portion may further include another component without excluding another component unless otherwise stated. “At least any one of X, Y, and Z” and “at least any one selected from a group consisting of X, Y, and Z” may be interpreted as one X, one Y, one Z, or any combination of two or more of X, Y, and Z (for example, XYZ, XYY, YZ, and ZZ). Here, “and/or” includes all combinations of one or more of corresponding configurations.

Here, terms such as first and second may be used to describe various components, but these components are not limited to these terms. These terms are used to distinguish one component from another component. Therefore, a first component may refer to a second component within a range without departing from the scope disclosed herein.

Spatially relative terms such as “under”, “on”, and the like may be used for descriptive purposes, thereby describing a relationship between one element or feature and another element(s) or feature(s) as shown in the drawings. Spatially relative terms are intended to include other directions in use, in operation, and/or in manufacturing, in addition to the direction depicted in the drawings. For example, in case that a device shown in the drawing is turned upside down, elements depicted as being positioned “under” other elements or features are positioned in a direction “on” the other elements or features. Therefore, in an embodiment, the term “under” may include both directions of on and under. The device may face in other directions (for example, rotated 90 degrees or in other directions) and thus the spatially relative terms used herein are interpreted according thereto.

Various embodiments are described with reference to drawings schematically illustrating ideal embodiments. Accordingly, it will be expected that shapes may vary, for example, according to tolerances and/or manufacturing techniques. Therefore, the embodiments disclosed herein cannot be construed as being limited to shown specific shapes, and should be interpreted as including, for example, changes in shapes that occur as a result of manufacturing. As described above, the shapes shown in the drawings may not show actual shapes of areas of a device, and the present embodiments are not limited thereto.

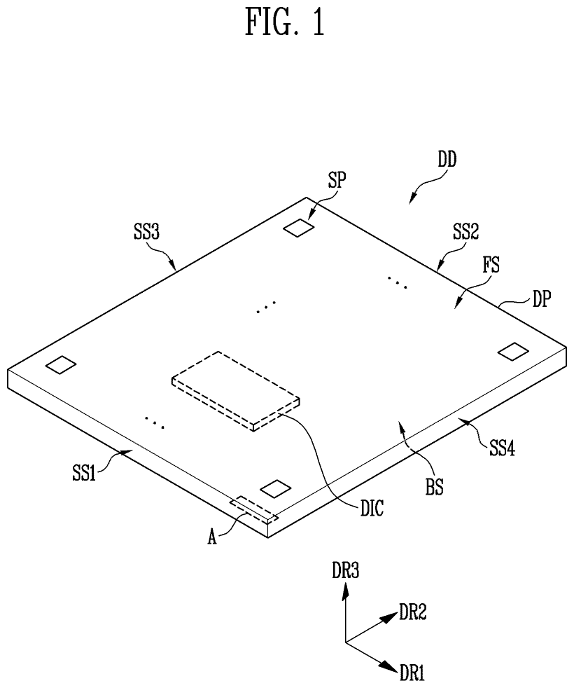

FIG. 1 is a schematic perspective view illustrating a display device according to an embodiment of the disclosure.

Referring to FIG. 1, the display device DD may include a display panel DP and a driver integrated circuit DIC.

The display panel DP may include sub-pixels SP. The sub-pixels SP may generate light of two or more colors. Among the sub-pixels SP, two or more sub-pixels may configure one pixel. According to combination of light emitted from sub-pixels included in the pixel, the pixel may emit light of various colors and various luminances.

The driver integrated circuit DIC may control the display panel DP and/or the sub-pixels SP. The driver integrated circuit DIC may control the display panel DP and/or the sub-pixels SP in response to external control signals and data signals, and thus an image may be displayed through the sub-pixels SP.

The display panel DP may have an upper surface FS, a lower surface BS opposite to the upper surface FS, and first to fourth side surfaces SS1 to SS4 connecting the upper surface FS and the lower surface BS. The light emitted from the sub-pixels SP may be output through the upper surface FS of the display panel DP. For example, the upper surface FS of the display panel DP may correspond to a display surface.

In order to reduce a non-display area of the display panel DP, the driver integrated circuit DIC may be disposed on the lower surface BS of the display panel DP. For example, the display panel DP may include side surface connection lines disposed on at least one of the first to fourth side surfaces SS1 to SS4. The driver integrated circuit DIC may be electrically connected to components of the display panel DP through the side surface connection lines.

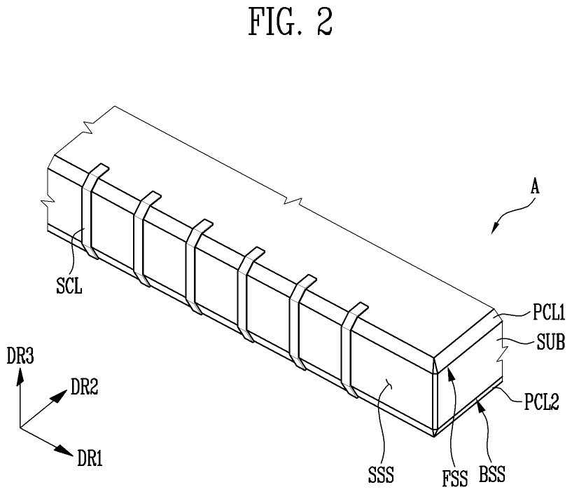

FIG. 2 is an enlarged schematic perspective view illustrating configurations of the display panel in an area A of FIG. 1.

Referring to FIGS. 1 and 2, the display device DD may include a substrate SUB, a first pixel circuit layer PCL1, a second pixel circuit layer PCL2, and side surface connection lines SCL.

The substrate SUB may include an upper surface FSS and a lower surface BSS facing each other in a third direction DR3 (or a thickness direction). The upper surface FSS of the substrate SUB may face the upper surface FS of the display panel DP. The lower surface BSS of the substrate SUB faces the lower surface BS of the display panel DP. The substrate SUB may include a side surface SSS (or an edge area) connecting the upper surface FSS and the lower surface BSS. The side surface SSS may be the outermost portion of the substrate SUB.

The first pixel circuit layer PCL1 may be disposed on the upper surface FSS of the substrate SUB. Light emitting elements may be disposed on the first pixel circuit layer PCL1. The first pixel circuit layer PCL1 may include upper conductive patterns electrically connected to the light emitting elements and one or more insulating layers disposed between the upper conductive patterns. For example, the upper conductive patterns may include transistors, signal lines, and the like.

The second pixel circuit layer PCL2 may be disposed on the lower surface BSS of the substrate SUB. The first pixel circuit layer PCL1 and the second pixel circuit layer PCL2 may be disposed on opposite sides with respect to the substrate SUB in the third direction DR3 (e.g., thickness direction). The second pixel circuit layer PCL2 may include lower conductive patterns electrically connecting the side surface connection lines SCL to the driver integrated circuit DIC and one or more insulating layers disposed between the lower conductive patterns.

The side surface connection lines SCL may be disposed on the side surface SSS of the substrate SUB. The side surface connection lines SCL may electrically connect a portion of the upper conductive patterns of the first pixel circuit layer PCL1 to the lower conductive patterns of the second pixel circuit layer PCL2. An end of each of the side surface connection lines SCL may contact one of the upper conductive patterns, and another end of the corresponding side surface connection line may contact one of the lower conductive patterns. The upper conductive patterns may include fan out lines, and the fan out lines may be electrically connected to the driver integrated circuit DIC through the side surface connection lines SCL and the lower conductive patterns.

As described above, as the display device DD includes the side surface connection line SCL for connecting the fan out lines to the driver integrated circuit DIC, the non-display area may be minimized in the upper surface FSS of the substrate SUB or the upper surface FS of the display panel DP.

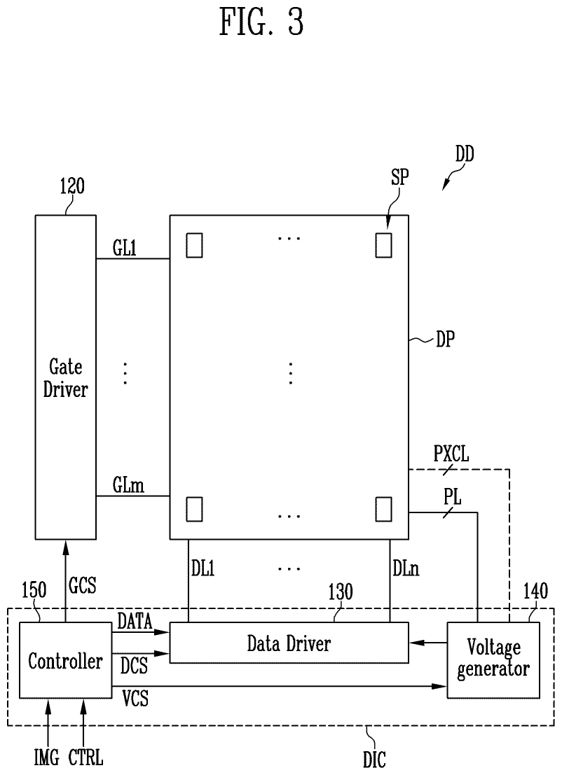

FIG. 3 is a schematic block diagram illustrating an embodiment of the display device of FIG. 1.

Referring to FIG. 3, the display device DD may include a display panel DP, a gate driver 120, a data driver 130, a voltage generator 140, and a controller 150.

The sub-pixels SP of the display panel DP may be electrically connected to the gate driver 120 through first to m-th gate lines GL1 to GLm. The sub-pixels SP may be electrically connected to the data driver 130 through first to n-th data lines DL1 to DLn.

The gate driver 120 may be electrically connected to the sub-pixels SP arranged in a row direction through the first to m-th gate lines GL1 to GLm. The gate driver 120 may output gate signals to the first to m-th gate lines GL1 to GLm in response to a gate control signal GCS. The gate control signal GCS may include a start signal indicating a start of each frame, a horizontal synchronization signal, and the like.

The gate driver 120 may be disposed on one side of the display panel DP. However, embodiments are not limited thereto. For example, the gate driver 120 may be divided into two or more physically and/or logically divided drivers, and such drivers may be disposed on one side of the display panel DP and another side of the display panel DP opposite the one side. The gate driver 120 may be integrated into the display panel DP.

The data driver 130 may be electrically connected to the sub-pixels SP arranged in a column direction through the first to n-th data lines DL1 to DLn. The data driver 130 receives an image data DATA and a data control signal DCS from the controller 150. The data driver 130 may operate in response to the data control signal DCS. The data control signal DCS may include a source start signal, a source shift clock, a source output enable signal, and the like.

The data driver 130 may receive voltages from the voltage generator 140. The data driver 130 may apply data signals having grayscale voltages corresponding to the image data DATA to the first to n-th data lines DL1 to DLn using the received voltages. In case that the gate signal is applied to each of the first to m-th gate lines GL1 to GLm, the data signals corresponding to the image data DATA may be applied to the data lines DL1 to DLn. Accordingly, the sub-pixels SP may generate light corresponding to the data signals, and the display panel DP may display an image (or images).

The gate driver 120 and the data driver 130 may include complementary metal-oxide semiconductor (CMOS) circuit elements.

The voltage generator 140 may operate in response to a voltage control signal VCS from the controller 150. The voltage generator 140 may generate multiple voltages and provide the generated voltages to components of the display device DD such as the gate driver 120, the data driver 130, and the controller 150. The voltage generator 140 may generate multiple voltages by receiving an input voltage from an outside of the display device DD and regulating the received voltage.

The voltage generator 140 may generate a first power voltage and a second power voltage. The generated first and second power voltages may be provided to the sub-pixels SP through power lines PL. In other embodiments, at least one of the first and second power voltages may be provided from the outside of the display device DD.

The voltage generator 140 may provide various voltages and/or signals. For example, the voltage generator 140 may provide one or more initialization voltages applied to the sub-pixels SP. For example, during a sensing operation for sensing electrical characteristics of transistors and/or light emitting elements of the sub-pixels SP, a predetermined reference voltage may be applied to the first to n-th data lines DL1 to DLn, and the voltage generator 140 may generate the reference voltage and transmit the reference voltage to the data driver 130. For example, during a display operation for displaying an image on the display panel DP, common pixel control signals may be applied to the sub-pixels SP, and the voltage generator 140 may generate the pixel control signals. The voltage generator 140 may provide the pixel control signals to the sub-pixels SP through pixel control lines PXCL. As depicted in FIG. 1, the pixel control lines PXCL are electrically connected between the voltage generator 140 and the display panel DP, but embodiments are not limited thereto. For example, the pixel control lines PXCL may be electrically connected between the gate driver 120 and the display panel DP. For example, the pixel control signals may be transmitted from the voltage generator 140 to the pixel control lines PXCL through the gate driver 120.

The controller 150 may control overall operations of the display device DD. The controller 150 may receive an input image data IMG and a control signal CTRL corresponding thereto from an external source. The controller 150 may provide the gate control signal GCS, the data control signal DCS, and the voltage control signal VCS in response to the control signal CTRL.

The controller 150 may convert the input image data IMG so that the input image data IMG is suitable for the display device DD or the display panel DP and output the image data DATA. The controller 150 may output the image data DATA by aligning the input image data IMG so that the input image data IMG is suitable for the sub-pixels SP of a row unit.

The data driver 130, the voltage generator 140, and the controller 150 may be included in the driver integrated circuit DIC. For example, the data driver 130, the voltage generator 140, and the controller 150 may be functionally divided components in one driver integrated circuit DIC. In other embodiments, at least one of the data driver 130, the voltage generator 140, and the controller 150 may be provided as a component distinguished from the driver integrated circuit DIC. As shown in FIG. 1, the driver integrated circuit DIC may be disposed on the lower surface of the display panel DP.

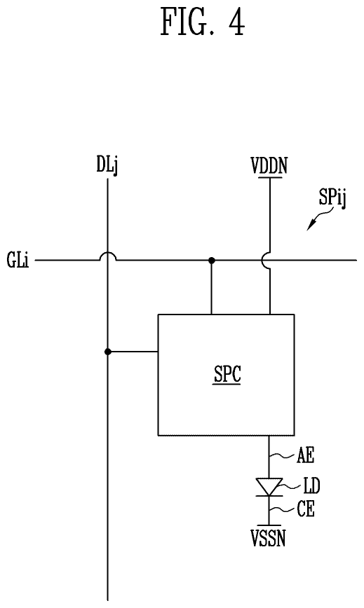

FIG. 4 is a schematic block diagram illustrating an embodiment of one of the sub-pixels of FIG. 3. As depicted in FIG. 4, among the sub-pixels SP of FIG. 3, a sub-pixel SPij arranged in an i-th row (i is an integer greater than or equal to 1 and less than or equal to m) and a j-th column (j is an integer greater than or equal to 1 and less than or equal to n) is shown as an example.

Referring to FIG. 4, the sub-pixel SPij may include a sub-pixel circuit SPC and a light emitting element LD.

The light emitting element LD may be electrically connected between a first power voltage node VDDN and a second power voltage node VSSN. The first power voltage node VDDN may be electrically connected to one of the power lines PL of FIG. 3 and may receive the first power voltage. The second power voltage node VSSN may be electrically connected to another one of the power lines PL of FIG. 3 and may receive the second power voltage. The first power voltage may have a voltage level higher than that of the second power voltage.

The light emitting element LD may be electrically connected between an anode electrode AE and a cathode electrode CE. The anode electrode AE may be electrically connected to the first power voltage node VDDN through the sub-pixel circuit SPC. For example, the anode electrode AE may be electrically connected to the first power voltage node VDDN through one or more transistors included in the sub-pixel circuit SPC. The cathode electrode CE may be electrically connected to the second power voltage node VSSN. The light emitting element LD may emit light according to a current flowing from the anode electrode AE to the cathode electrode CE.

The sub-pixel circuit SPC may be electrically connected to an i-th gate line GLi among the first to m-th gate lines GL1 to GLm of FIG. 3, and a j-th data line DLj among the first to n-th data lines DL1 to DLn of FIG. 3. In response to a gate signal received through the i-th gate line GLi, the sub-pixel circuit SPC may control the light emitting element LD to emit light according to a data signal received through the j-th data line DLj. The sub-pixel circuit SPC may be further electrically connected to the pixel control lines PXCL of FIG. 3. For example, the sub-pixel circuit SPC may control the light emitting element LD in further response to the pixel control signals received through the pixel control lines PXCL.

For such operations, the sub-pixel circuit SPC may include circuit elements, for example, transistors and one or more capacitors.

The transistors of the sub-pixel circuit SPC may include P-type transistors and/or N-type transistors. The transistors of the sub-pixel circuit SPC may include a metal oxide silicon field effect transistor (MOSFET). The transistors of the sub-pixel circuit SPC may include an amorphous silicon semiconductor, a monocrystalline silicon, a polycrystalline silicon semiconductor, an oxide semiconductor, and the like.

FIG. 5 is a schematic plan view illustrating an embodiment of the display panel of FIG. 1.

Referring to FIG. 5, the display panel DP may include a display area DA and a non-display area NDA. The display panel DP may display an image (or images) through the display area DA. The non-display area NDA may be disposed around the display area DA.

The display panel DP may include the sub-pixels SP in the display area DA. The sub-pixels SP may be arranged along a first direction DR1 and a second direction DR2 crossing the first direction DR1. The first direction DR1 may be a row direction, and the second direction DR2 may be a column direction. The sub-pixels SP may be arranged in a matrix form along the first direction DR1 and the second direction DR2. However, embodiments are not limited thereto. For example, the sub-pixels SP may be arranged in a zigzag form along the first direction DR1 and the second direction DR2.

Two or more sub-pixels among multiple sub-pixels SP may configure one pixel PXL. As depicted in FIG. 5, the pixel PXL may include three sub-pixels SP1 to SP3, but embodiments are not limited thereto. For example, the pixel PXL may include two sub-pixels. Hereinafter, for convenience of description, it is assumed that the pixel PXL includes the first to third sub-pixels SP1 to SP3.

Each of the first to third sub-pixels SP1 to SP3 may generate light of one of various colors such as red, green, blue, cyan, magenta, and yellow. Hereinafter, for clear and concise description, it is assumed that the first sub-pixel SP1 may generate light of a red color, the second sub-pixel SP2 may generate light of a green color, and the third sub-pixel SP3 may generate light of a blue color.

Each of the first to third sub-pixels SP1, SP2, and SP3 may include at least one light emitting element to generate light. The light emitting elements of the first to third sub-pixels SP1 to SP3 may generate light of different colors. For example, the light emitting elements of the first to third sub-pixels SP1 to SP3 may generate the light of the red color, the green color, and the blue color, respectively.

In other embodiments, the light emitting elements of the first to third sub-pixels SP1 to SP3 may generate light of the same color. For example, the light emitting elements of the first to third sub-pixels SP1 to SP3 may generate light of a blue color. For example, the display panel DP may include a first light conversion pattern disposed on the first sub-pixel SP1 and a second light conversion pattern disposed on the second sub-pixel SP2. The first light conversion pattern may convert the light of the blue color into the light of the red color. The second light conversion pattern may convert the light of the blue color into the light of the green color. For example, the first light conversion pattern may include quantum dots that convert the light of the blue color into the light of the red color, and the second light conversion pattern may include quantum dots that convert the light of the blue color into the light of the green color. The display panel DP may further include a light functional pattern disposed on the third sub-pixel SP3 and to scatter the light of the blue color.

As a display panel DP, a display panel capable of self-emission such as a light emitting diode display panel (LED display panel) that uses a micro scale or nano scale of light emitting diode as the light emitting element, or an organic light emitting display panel (OLED panel) that uses an organic light emitting diode as the light emitting element may be used.

In the non-display area NDA, components for controlling the sub-pixels SP may be disposed. Lines, for example, the first to m-th gate lines GL1 to GLm, the first to n-th data lines DL1 to DLn, the power lines PL, and the pixel control lines PXCL of FIG. 3 may be disposed in the non-display area NDA.

The gate driver 120 of FIG. 3 may be disposed in the non-display area NDA. The gate driver 120 may be electrically connected to the sub-pixels SP through the first to m-th gate lines GL1 to GLm. For example, lines transmitting the gate control signal GCS of FIG. 3 may be further disposed in the non-display area NDA.

The display panel DP may have the first to fourth side surfaces SS1 to SS4. The first side surface SS1 may be parallel to the first direction DR1, and the second side surface SS2 may be parallel to the first direction DR1 and may be opposite to the first side surface SS1. The third side surface SS3 may be parallel to the second direction DR2 and connect the first and second side surfaces SS1 and SS2. The fourth side surface SS4 may be opposite to the third side surface SS3 and connect the first and second side surfaces SS1, SS2.

The lines may include first to p-th fan out lines FOL1 to FOLp. The first to p-th fan out lines FOL1 to FOLp may be disposed in the non-display area NDA adjacent to at least one of the first to fourth side surfaces SS1 to SS4. For example, the first to p-th fan out lines FOL1 to FOLp are shown to be disposed in the non-display area NDA adjacent to the first side surface SS1. For example, the first to p-th fan out lines FOL1 to FOLp may extend in the second direction DR2. However, embodiments are not limited thereto. For example, additional fan out lines may be disposed in the non-display area NDA adjacent to the second side surface SS2.

The first to p-th fan out lines FOL1 to FOLp may be electrically connected to various other lines. A portion of the first to p-th fan out lines FOL1 to FOLp may be electrically connected to lines electrically connected to the sub-pixels SP. For example, a portion of the first to p-th fan out lines FOL1 to FOLp may be electrically connected to the first to n-th data lines DL1 to DLn, the power lines PL, and the pixel control lines PXCL. Another portion of the first to p-th fan out lines FOL1 to FOLp may be electrically connected to lines transmitting the gate control signal GCS to the gate driver 120.

The driver integrated circuit DIC of FIG. 3 may be disposed on the lower surface (refer to BS of FIG. 1) of the display panel DP, and may be electrically connected to the first to p-th fan out lines OFL1 to OFLp through the side surface connection lines SCL of FIG. 2. Accordingly, the driver integrated circuit DIC may be electrically connected to the sub-pixels SP and the gate driver 120 through the side surface connection lines SCL and the first to p-th fan out lines FOL1 to FOLp.

The display area DA may have various shapes. The display area DA may have a closed loop shape including sides of a straight line and/or a curved line. For example, the display area DA may have shapes of a polygon, a circle, a semicircle, an ellipse, and the like.

The display panel DP may have a flat display surface. In other embodiments, the display panel DP may have a display surface that is at least partially round. The display panel DP may be bendable, foldable, or rollable. In such cases, the display panel DP and/or a substrate of the display panel DP may include materials having a flexible property.

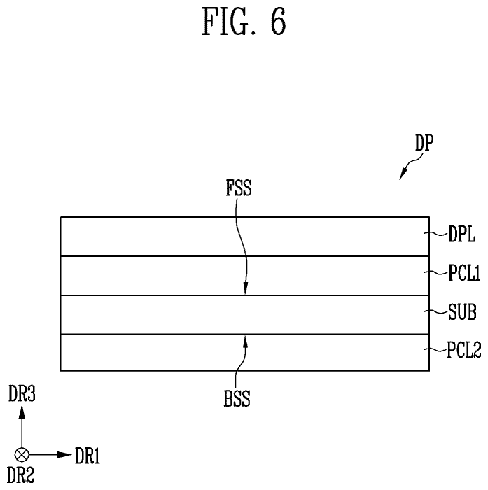

FIG. 6 is a schematic cross-sectional view illustrating an embodiment of the display panel of FIG. 5.

Referring to FIG. 6, the display panel DP may include the substrate SUB, the first pixel circuit layer PCL1, a display element layer DPL, and the second pixel circuit layer PCL2.

The substrate SUB may be formed of an insulating material such as glass or resin. For example, the substrate SUB may include a glass substrate. As another example, the substrate SUB may include a polyimide (PI) substrate. As still another example, the substrate SUB may include a silicon wafer substrate formed using a semiconductor process.

The substrate SUB may be formed of a flexible material that may be bent or folded, and may have a single-layer structure or a multi-layer structure. For example, the flexible material may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate. However, embodiments are not limited thereto.

The first pixel circuit layer PCL1 may be disposed on the upper surface FSS of the substrate SUB in the third direction DR3 (e.g., thickness direction). The first pixel circuit layer PCL1 may include insulating layers and semiconductor patterns and conductive patterns disposed between the insulating layers. The conductive patterns of the first pixel circuit layer PCL1 may function as circuit elements, lines, and the like.

The circuit elements of the first pixel circuit layer PCL1 may include the sub-pixel circuit SPC (refer to FIG. 2) of each of the sub-pixels SP of FIG. 5. For example, the circuit elements of the first pixel circuit layer PCL1 may be provided as transistors and one or more capacitors of the sub-pixel circuit SPC.

The lines of the first pixel circuit layer PCL1 may include various signal lines and/or voltage lines necessary to drive the display element layer DPL. The lines of the first pixel circuit layer PCL1 may include the first to m-th gate lines GL1 to GLm of FIG. 3, the first to n-th data lines DL1 to DLn of FIG. 3, and the power line PL of FIG. 3, the pixel control lines PXCL of FIG. 3, lines transmitting the gate control signal GCS of FIG. 3, and the fan out lines FOL1 to FOLp of FIG. 5.

The display element layer DPL may be disposed on the first pixel circuit layer PCL1 in the third direction DR3 (e.g., thickness direction). The display element layer DPL may include light emitting elements of the sub-pixels SP.

Although not shown in FIG. 6, a light functional layer may be disposed on the display element layer DPL. The light functional layer may include light conversion patterns having color conversion particles and/or scattering particles. For example, the color conversion particles may include quantum dots. The quantum dots may change a wavelength (or a color) of light emitted from the display element layer DPL. The light functional layer may further include light functional patterns having scattering particles. The light conversion patterns and the light scattering patterns may be omitted.

The light functional layer may further include a color filter layer including color filters. The color filter may selectively transmit light of a specific wavelength (or a specific color). The color filter layer may be omitted.

A window for protecting an exposed surface (or an upper surface) of the display panel DP may be provided on the light functional layer. The window may protect the display panel DP from external shock. The window may be coupled to the light functional layer through an optically transparent adhesive (or cohesive) member. The window may have a multiple layer structure selected from a glass substrate, a plastic film, and a plastic substrate. The multiple layer structure may be formed through a continuous process or an adhesion process using an adhesive layer. All or a portion of the window may have flexibility.

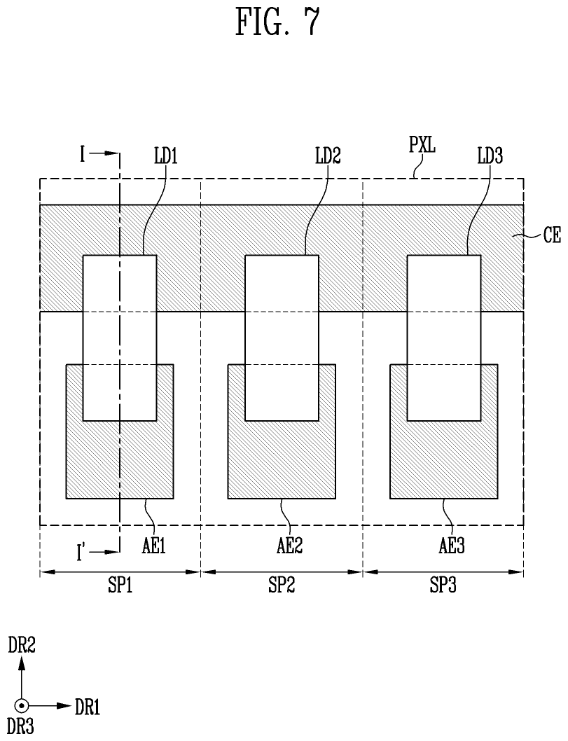

FIG. 7 is a schematic plan view illustrating an embodiment of the pixel of FIG. 5.

Referring to FIG. 7, the pixel PXL may include the first to third sub-pixels SP1 to SP3. The first to third sub-pixels SP1 to SP3 may be arranged in the first direction DR1. However, an arrangement of the pixel PXL is not limited thereto and may vary according to embodiments. For example, the first to third sub-pixels SP1 to SP3 may be arranged in a zigzag form.

The first to third anode electrodes AE1 to AE3 may be disposed in the first to third sub-pixels SP1 to SP3, respectively. The first anode electrode AE1 may be provided as the anode electrode AE (refer to FIG. 4) electrically connected to the sub-pixel circuit SPC (refer to FIG. 4) of the first sub-pixel SP1. The second anode electrode AE2 may be provided as the anode electrode AE electrically connected to the sub-pixel circuit SPC of the second sub-pixel SP2. The third anode electrode AE3 may be provided as the anode electrode AE electrically connected to the sub-pixel circuit SPC of the third sub-pixel SP3.

The cathode electrode CE may be spaced apart from the first to third anode electrodes AE1 to AE3. The cathode electrode CE may be disposed at the same height as the first to third anode electrodes AE1 to AE3. The cathode electrode CE may be spaced apart from the first to third anode electrodes AE1 to AE3 in the second direction DR2. The cathode electrode CE may extend in the first direction DR1 and may be used as a common electrode for the pixel PXL and other pixels adjacent to the pixel PXL. Although not shown, the cathode electrode CE may extend not only in the first direction DR1 but also in the second direction DR2 and may be used as a common electrode for all sub-pixels SP of FIG. 3. As described above, the cathode electrode CE may have various shapes.

First to third light emitting elements LD1 to LD3 may be disposed on the first to third anode electrodes AE1 to AE3 and the cathode electrode CE. The first light emitting element LD1 may be electrically connected to the first anode electrode AE1 and the cathode electrode CE. The first light emitting element LD1 may be provided as the light emitting element LD (refer to FIG. 4) electrically connected to the sub-pixel circuit SPC of the first sub-pixel SP1. The second light emitting element LD2 may be electrically connected to the second anode electrode AE2 and the cathode electrode CE. The second light emitting element LD2 may be provided as the light emitting element LD electrically connected to the sub-pixel circuit SPC of the second sub-pixel SP2. The third light emitting element LD3 may be electrically connected to the third anode electrode AE3 and the cathode electrode CE. The third light emitting element LD3 may be provided as the light emitting element LD electrically connected to the sub-pixel circuit SPC of the third sub-pixel SP3.

The first light emitting element LD1, the second light emitting element LD2, and the third light emitting element LD3 may be inorganic light emitting diodes including an inorganic light emitting material. However, embodiments are not limited thereto, and for example, organic light emitting diodes may be used.

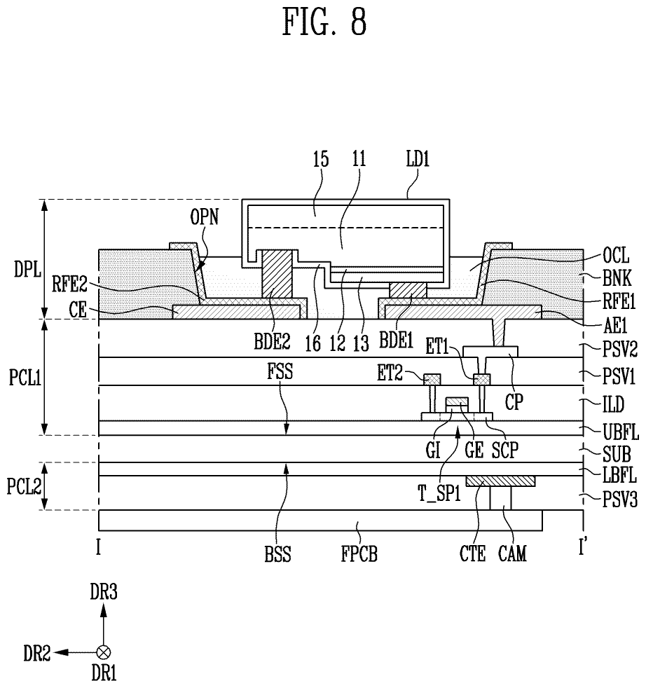

FIG. 8 is a schematic cross-sectional view taken along line I-I′ of FIG. 7.

Referring to FIGS. 7 and 8, the first pixel circuit layer PCL1 and the display element layer DPL may be sequentially disposed on the upper surface FSS of the substrate SUB in the third direction DR3 (e.g., thickness direction), and the second pixel circuit layer PCL2 may be disposed on the lower surface BSS of the substrate SUB in the third direction DR3 (e.g., thickness direction).

The first pixel circuit layer PCL1 may include insulating layers, semiconductor patterns, and conductive patterns stacked on the substrate SUB. The insulating layers may include an upper buffer layer UBFL, one or more interlayer insulating layers ILD, and one or more passivation layers PSV1 and PSV2. The semiconductor patterns and the conductive patterns may be positioned between the insulating layers. The conductive patterns may include at least one of copper (Cu), molybdenum (Mo), tungsten (W), aluminum neodymium (AlNd), titanium (Ti), aluminum (Al), and silver (Ag).

As described with reference to FIG. 4, the sub-pixel circuit SPC (refer to FIG. 4) of each of the first to third sub-pixels SP1 to SP3 may include transistors and one or more capacitors. The semiconductor patterns and the conductive patterns of the first pixel circuit layer PCL1 may be used as the transistors and the capacitors of the sub-pixel circuit SPC. The conductive patterns of the first pixel circuit layer PCL1 may be further provided as lines. For example, the conductive patterns of the first pixel circuit layer PCL1 may be provided as the first to m-th gate lines GL1 to GLm of FIG. 3, the first to n-th data lines DL1 to DLn of FIG. 3, the power lines PL of FIG. 3, the pixel control lines PXCL of FIG. 3, the lines transmitting the gate control signal GCS of FIG. 3, and the fan out lines FOL1 to FOLp of FIG. 5.

The upper buffer layer UBFL may be disposed on the upper surface FSS of the substrate SUB. The upper buffer layer UBFL may prevent an impurity from diffusing into the circuit elements and the lines included in the first pixel circuit layer PCL1. The upper buffer layer UBFL may include an inorganic insulating layer including an inorganic material. The upper buffer layer UBFL may include at least one of metal oxides such as silicon nitride (SiNₓ), silicon oxide (SiOₓ), silicon oxynitride (SiOₓN_{y}), and aluminum oxide (AlOₓ). The upper buffer layer UBFL may be provided as a single layer or multiple layers. In case that the upper buffer layer UBFL is provided in the multiple layers, each layer may be formed of the same material or may be formed of different materials.

One or more barrier layers may be disposed between the substrate SUB and the upper buffer layer UBFL. Each of the barrier layers may include polyimide.

A transistor T_SP1 may be disposed on the upper buffer layer UBFL. The transistor T_SP1 may be one of the transistors of the sub-pixel circuit SPC included in the first sub-pixel SP1. For example, the transistor T_SP1 may be understood as a transistor electrically connected to the first anode electrode AE1 among the transistors of the sub-pixel circuit SPC.

The transistor T_SP1 may include a semiconductor pattern SCP, a gate electrode GE, a first terminal ET1, and a second terminal ET2. The first terminal ET1 may be one of a source electrode and a drain electrode, and the second terminal ET2 may be the other one of the source electrode and the drain electrode. For example, the first terminal ET1 may be the source electrode, and the second terminal ET2 may be the drain electrode.

The semiconductor pattern SCP may be disposed on the upper buffer layer UBFL. The semiconductor pattern SCP may include a first contact area contacting the first terminal ET1 and a second contact area contacting the second terminal ET2. An area between the first contact area and the second contact area may be a channel area. The channel area may overlap the gate electrode GE of the transistor T_SP1. The channel area may be a semiconductor pattern that is not doped with an impurity and may be an intrinsic semiconductor. The first contact area and the second contact area may be semiconductor patterns doped with an impurity. As the impurity, for example, a p-type impurity may be used, but embodiments are not limited thereto.

The semiconductor pattern SCP may include one of various types of semiconductors, such as an amorphous silicon semiconductor, a monocrystalline silicon semiconductor, a polycrystalline silicon semiconductor, a low temperature poly silicon semiconductor, and an oxide semiconductor.

Interlayer insulating layers ILD sequentially stacked on the semiconductor pattern SCP may be disposed. The interlayer insulating layers ILD may be inorganic insulating layers including inorganic materials. For example, each of the interlayer insulating layers ILD may include at least one of metal oxides such as silicon nitride (SiNₓ), silicon oxide (SiOₓ), silicon oxynitride (SiOₓN_{y}), and aluminum oxide (AlOₓ). However, interlayer insulating layers ILD are not limited thereto. For example, one of the interlayer insulating layers ILD may include an organic insulating layer including an organic material.

The interlayer insulating layers ILD may electrically separate conductive patterns and/or semiconductor patterns disposed between the interlayer insulating layers ILD from each other. For example, the interlayer insulating layers ILD may include a gate insulating layer GI disposed on the semiconductor pattern SCP. The gate insulating layer GI may be disposed between the semiconductor pattern SCP and the gate electrode GE so that the gate electrode GE is spaced apart from the semiconductor pattern SCP. The gate insulating layer GI may be entirely provided on the semiconductor pattern SCP and the upper buffer layer UBFL to cover the semiconductor pattern SCP and the upper buffer layer UBFL. As the number of layers required to form the conductive patterns and/or the semiconductor patterns increases, the number of interlayer insulating layers ILD may increase.

The gate electrode GE may be disposed on the gate insulating layer GI. The gate electrode GE may overlap the channel area of the semiconductor pattern SCP. The gate electrode GE may be provided as a single layer including at least one material among copper (Cu), molybdenum (Mo), tungsten (W), aluminum neodymium (AlNd), titanium (Ti), aluminum (Al), and silver (Ag). The gate electrode GE may be provided as multiple layers including at least one material among molybdenum (Mo), titanium (Ti), copper (Cu), aluminum (Al), and silver (Ag) which are low-resistance materials.

The first and second terminals ET1 and ET2 may be disposed on the interlayer insulating layers ILD. The first and second terminals ET1 and ET2 may contact the semiconductor pattern SCP through contact holes passing through the interlayer insulating layers ILD. The first and second terminals ET1 and ET2 may respectively contact the first and second contact areas of the semiconductor pattern SCP. Each of the first and second terminals ET1 and ET2 may include at least one material among copper (Cu), molybdenum (Mo), tungsten (W), aluminum neodymium (AlNd), titanium (Ti), aluminum (Al), and silver (Ag).

Although the first and second terminals ET1 and ET2 are shown as separate electrodes electrically connected to the semiconductor pattern SCP, embodiments are not limited thereto. The first terminal ET1 may be a first contact area adjacent to one side of the channel area of the semiconductor pattern SCP, and the second terminal ET2 may be a second contact area adjacent to another side of the channel area. For example, the first terminal ET1 may be electrically connected to the light emitting element LD through a connection means such as a bridge electrode disposed on at least one of the interlayer insulating layers ILD.

The transistor T_SP1 may be configured of a low-temperature poly silicon transistor. However, embodiments are not limited thereto. For example, the transistor T_SP1 may be configured of an oxide semiconductor transistor. The sub-pixel circuit of the first sub-pixel SP1 may include different types of transistors. For example, the transistor T_SP1 may be configured of a low-temperature poly silicon transistor, and another transistor of the first sub-pixel SP1 may be configured of an oxide semiconductor transistor. For example, an oxide semiconductor of the corresponding oxide semiconductor transistor may be disposed on one of the interlayer insulating layers ILD rather than an insulating layer where the semiconductor pattern SCP of the transistor T_SP1 is disposed.

As depicted in FIG. 8, the transistor T_SP1 is shown as having a top gate structure, but embodiments of the transistor T_SP1 is not limited thereto. For example, the transistor T_SP1 may be a transistor of a bottom gate structure. A structure of the transistor T_SP1 may be variously changed.

At least a portion of various line lines of the display panel DP and/or the display device DD may be further disposed on the interlayer insulating layers ILD.

A first passivation layer PSV1 may be disposed on the interlayer insulating layers ILD and the first and second terminals ET1 and ET2. The passivation layer may also be referred to as a protective layer or a via layer. The first passivation layer PSV1 may protect components disposed thereunder and may provide a flat upper surface.

A connection pattern CP may be disposed on the first passivation layer PSV1. The connection pattern CP may be electrically connected to the first terminal ET1 of the transistor T_SP1 by passing through the first passivation layer PSV1. The connection pattern CP may include at least one material among copper (Cu), molybdenum (Mo), tungsten (W), aluminum neodymium (AlNd), titanium (Ti), aluminum (Al), and silver (Ag).

At least a portion of the various lines of the display panel DP and/or the display device DD may be further disposed on the first passivation layer PSV1.

A second passivation layer PSV2 may be disposed on the connection pattern CP and the first passivation layer PSV1. The second passivation layer PSV2 may protect components disposed thereunder and may provide a flat upper surface.

Each of the first and second passivation layers PSV1 and PSV2 may include an inorganic insulating layer including an inorganic material and/or an organic insulating layer including an organic material. The inorganic insulating layer may include, for example, at least one of metal oxides such as silicon oxide (SiOₓ), silicon nitride (SiNₓ), silicon oxynitride (SiOₓN_{y}), and aluminum oxide (AlOₓ). The organic insulating layer may include, for example, at least one of acrylic resin, epoxy resin, phenol resin, polyamide resin, polyimide resin, unsaturated polyester resin, poly-phenylene ether resin, poly-phenylene sulfide resin, and benzocyclobutene resin.

The first and second passivation layers PSV1 and PSV2 may include the same material as one of the interlayer insulating layers ILD, but embodiments are not limited thereto. Each of the first and second passivation layers PSV1 and PSV2 may be provided as a single layer, but may also be provided as multiple layers.

The display element layer DPL may be disposed on the second passivation layer PSV2. The display element layer DPL may include the first anode electrode AE1, the cathode electrode CE, the bank BNK, first and second reflective electrodes RFE1 and RFE2, the first light emitting element LD1, and an overcoat layer OCL.

The first anode electrode AE1 and the cathode electrode CE may be disposed on the first pixel circuit layer PCL1.

The first anode electrode AE1 may be electrically connected to the connection electrode CP through a contact hole passing through the second passivation layer PSV2. As described above, the first anode electrode AE1 may be electrically connected to the first transistor T_SP1.

The cathode electrode CE may be spaced apart from the first anode electrode AE1 in the first direction DR1. The cathode electrode CE may be electrically connected to the second power voltage node VSSN of FIG. 4. Accordingly, the second power voltage applied to the second power voltage node VSSN may be transmitted to the cathode electrode CE.

The bank BNK may be disposed on the first anode electrode AE1 and the cathode electrode CE. The bank BNK may have an opening OPN exposing portions of the first anode electrode AE1 and the cathode electrode CE. The first light emitting element LD1 may be disposed in the opening OPN of the bank BNK. As described above, the bank BNK may be provided as a pixel defining layer that defines an area where the first light emitting element LD1 is positioned.

The bank BNK may include a light blocking material to prevent light mixing between adjacent sub-pixels. The bank BNK may include an organic material. For example, the bank BNK may include an organic insulating material such as acryl resin, epoxy resin, phenol resin, polyamide resin, and polyimide resin.

The first reflective electrode RFE1 may be disposed on an exposed portion of the first anode electrode AE1 and a side surface of the bank BNK adjacent thereto. The second reflective electrode RFE2 may be disposed on an exposed portion of the cathode electrode CE and a side surface of the bank BNK adjacent thereto. The first and second reflective electrodes RFE1 and RFE2 may include conductive materials suitable for reflecting light. Accordingly, light emission efficiency of the first light emitting element LD1 may be improved. The first and second reflective electrodes RFE1 and RFE2 may include at least one among aluminum (Al), silver (Ag), magnesium (Mg), platinum (Pt), palladium (Pd), gold (Au), nickel (Ni), neodymium (Nd), iridium (Ir), chromium (Cr), titanium (Ti), and an alloy of two or more materials selected from them. However, embodiments are not limited thereto.

The first light emitting element LD1 may be electrically connected to the first anode electrode AE1 through the first reflective electrode RFE1. The first light emitting element LD1 may be electrically connected to the cathode electrode CE through the second reflective electrode RFE2. The first light emitting element LD1 may be bonded and coupled to the first and second reflective electrodes RFE1 and RFE2.

The first light emitting element LD1 may include a first semiconductor layer 11, an active layer 12, a second semiconductor layer 13, and an auxiliary layer 15. The first light emitting element LD1 may include a light emitting stack in which the auxiliary layer 15, the first semiconductor layer 11, the active layer 12, and the second semiconductor layer 13 are sequentially stacked in the third direction DR3 (e.g., thickness direction).

The first light emitting element LD1 may include first and second bonding electrodes BDE1 and BDE2 facing in the same direction (for example, a direction opposite to the third direction DR3). The first bonding electrode BDE1 may be electrically connected to the second semiconductor layer 13. The second bonding electrode BDE2 may be electrically connected to the first semiconductor layer 11 exposed by etching the second semiconductor layer 13 and the active layer 12. The first light emitting element LD1 may be a flip chip type light emitting element.

The first semiconductor layer 11 may provide an electron to the active layer 12. For example, the first semiconductor layer 11 may include at least one n-type semiconductor layer. For example, the first semiconductor layer 11 may include one semiconductor material among gallium nitride (GaN), aluminum gallium nitride (AlGaN), indium gallium nitride (InGaN), aluminum nitride (AlN), and indium nitride (InN), and may be an n-type semiconductor layer doped with a first conductive dopant (or an n-type dopant) such as silicon (Si), germanium (Ge), or tin (Sn). However, a material configuring the first semiconductor layer 11 is not limited thereto, and various other materials may configure the first semiconductor layer 11. The first semiconductor layer 11 may include a gallium nitride (GaN) semiconductor material doped with the first conductive dopant (or the n-type dopant). The first semiconductor layer 11 may form an n-type semiconductor layer together with the auxiliary layer 15.

The active layer 12 may be disposed on the first semiconductor layer 11 and may be an area where an electron and a hole recombine. As the electron and the hole recombine in the active layer 12, the electron and the hole may transition to a low energy level, and thus light having a wavelength corresponding thereto may be generated. The active layer 12 may be formed in a single or multiple quantum well structure. In case that the active layer 12 is formed in the multiple quantum well structure, a unit including a barrier layer, a strain reinforcing layer, and a well layer may be repeatedly stacked to form the active layer 12. However, embodiments of the active layer 12 are not limited thereto.

The second semiconductor layer 13 may be disposed on the active layer 12 and provide the hole to the active layer 12. The second semiconductor layer 13 may include a semiconductor layer of a type different from that of the first semiconductor layer 11. As an example, the second semiconductor layer 13 may include at least one p-type semiconductor layer. For example, the second semiconductor layer 13 may include at least one semiconductor material among gallium nitride (GaN), aluminum gallium nitride (AlGaN), indium gallium nitride (InGaN), aluminum nitride (AlN), and indium nitride (InN), and may be a p-type semiconductor layer doped with a second conductive dopant (or a p-type dopant) such as magnesium (Mg), zinc (Zn), calcium (Ca), strontium (Sr), or barium (Ba). However, a material configuring the second semiconductor layer 13 is not limited thereto, and various other materials may configure the second semiconductor layer 13. The second semiconductor layer 13 may include a gallium nitride (GaN) semiconductor material doped with the second conductive dopant (or the p-type dopant).

The auxiliary layer 15 may include a gallium nitride (GaN) semiconductor material that is not doped with an impurity, and may configure an n-type semiconductor layer together with the first semiconductor layer 11.

The first bonding electrode BDE1 may be electrically connected to the second semiconductor layer 13. The second bonding electrode BDE2 may be electrically connected to the first semiconductor layer 11. The first and second bonding electrodes BDE1 and BDE2 may include a eutectic metal.

The first light emitting element LD1 may further include an insulating layer 16 covering an outer peripheral surface of the light emitting stack. The insulating layer 16 may prevent an electrical short circuit that may occur in case that the active layer 12 comes into contact with a conductive material other than the first and second semiconductor layers 11 and 13. The insulating layer 16 may include a transparent insulating material. The insulating layer 16 may expose lower surfaces of the first and second bonding electrodes BDE1 and BDE2.

A lower surface of the first bonding electrode BDE1 may contact the first reflective electrode RFE1. Accordingly, the first bonding electrode BDE1 may be electrically connected to the first anode electrode AE1 through the first reflective electrode RFE1. A lower surface of the second bonding electrode BDE2 may contact the second reflective electrode RFE2. Accordingly, the second bonding electrode BDE2 may be electrically connected to the cathode electrode CE through the second reflective electrode RFE2.

The overcoat layer OCL may be disposed in the opening OPN where the first and second reflective electrodes RFE1 and RFE2 and the first light emitting element LD1 are disposed. The overcoat layer OCL may fix the first light emitting element LD1 bonded to the first and second reflective electrodes RFE1 and RFE2 so that the first light emitting element LD1 does not move. The overcoat layer OCL may protect configurations disposed thereunder from a foreign substance such as dust and moisture. For example, the overcoat layer OCL may include at least one of an inorganic insulating layer and an organic insulating layer. For example, the overcoat layer OCL may include epoxy, but embodiments are not limited thereto.

The light functional layer LFL may be disposed on the display element layer DPL. The light functional layer LFL may include a light conversion pattern and a color filter.

The light conversion pattern may include color conversion particles and/or scattering particles. The color conversion particles may change a wavelength of incident light and convert the incident light into light of a different color. The color conversion particles may scatter the incident light. The color conversion particles may be quantum dots. The scattering particles may scatter the incident light.

The first sub-pixel SP1 may be a red sub-pixel. In case that the first light emitting element LD1 emits the light of the blue color, the light conversion pattern may include color conversion particles to convert the light of the blue color into the light of the red color. In case that the first light emitting element LD1 emits the light of the red color, the light conversion pattern may include the scattering particles. As described above, particles included in the light conversion pattern may be variously changed according to the first light emitting element LD1.

The color filter may be disposed on the light conversion pattern. The color filter may overlap the light conversion pattern. The color filter may selectively transmit light of a desired wavelength range. In case that the first sub-pixel SP1 is the red sub-pixel, the color filter may include a red color filter.

The first pixel circuit layer PCL1 and the display element layer DPL of the first sub-pixel SP1 are described above. Each of the second and third sub-pixels SP2 and SP3 of FIG. 7 may be similarly configured to the first sub-pixel SP1, unless otherwise described herein.

The second pixel circuit layer PCL2 may be disposed on the lower surface BSS of the substrate SUB. The second pixel circuit layer PCL2 may include a lower buffer layer LBFL and at least one passivation layer PSV3.

The lower buffer layer LBFL may be disposed on the lower surface BSS of the substrate SUB. The lower buffer layer LBFL may protect the lower surface BSS of the substrate SUB. The lower buffer layer LBFL may include substantially the same material as the upper buffer layer UBFL. The lower buffer layer LBFL may include an inorganic insulating layer including an inorganic material. The lower buffer layer LBFL may include at least one of metal oxides such as silicon nitride (SiNₓ), silicon oxide (SiOₓ), silicon oxynitride (SiOₓN_{y}), and aluminum oxide (AlOₓ).

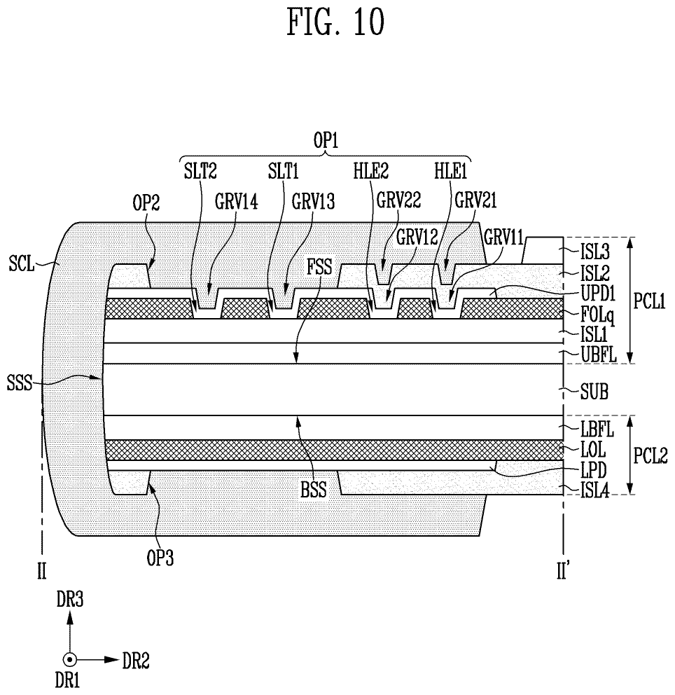

An intermediate electrode CTE may be disposed on the lower buffer layer LBFL. The intermediate electrode CTE may be electrically connected to a read-out line (refer to LOL of FIG. 10). The intermediate electrode CTE may transmit a voltage and/or a signal received from a flexible printed circuit board FPCB to the read-out line. The intermediate electrode CTE may be electrically connected to the flexible printed circuit board FPCB through a conductive member CAM. The intermediate electrode CTE may be one of conductive patterns disposed in the second pixel circuit layer PCL2.

The intermediate electrode CTE may have a multiple layer structure. For example, the intermediate electrode CTE may include a first intermediate electrode disposed on the lower buffer layer LBFL, and a second intermediate electrode disposed on the first intermediate electrode.

The first intermediate electrode may be a single layer formed from one of molybdenum, aluminum, chromium, gold, titanium, nickel, neodymium, and copper, or an alloy thereof. The second intermediate electrode may include a transparent conductive material.

The third passivation layer PSV3 may be disposed on the lower buffer layer LBFL and the intermediate electrode CTE. The third passivation layer PSV3 may include an inorganic insulating layer including an inorganic material and/or an organic insulating layer including an organic material. The inorganic insulating layer may include, for example, at least one of metal oxides such as silicon oxide (SiOₓ), silicon nitride (SiNₓ), silicon oxynitride (SiOₓN_{y}), and aluminum oxide (AlOₓ). The organic insulating layer may include, for example, at least one of acrylic resin, epoxy resin, phenol resin, polyamide resin, polyimide resin, unsaturated polyester resin, poly-phenylene ether resin, poly-phenylene sulfide resin, and benzocyclobutene resin.

The flexible printed circuit board FPCB may be disposed on the third passivation layer PSV3. The driver integrated circuit DIC described with reference to FIGS. 1 and 3 may be mounted on or electrically connected to the flexible printed circuit board FPCB. The flexible printed circuit board FPCB may transmit a signal and/or a voltage from the driver integrated circuit DIC to the intermediate electrode CTE.

The flexible printed circuit board FPCB may be electrically connected to the intermediate electrode CTE through the conductive member CAM passing through the third passivation layer PSV3. Accordingly, the flexible printed circuit board FPCB may supply a voltage and/or a signal to the fan out line disposed on the upper surface FSS of the board SUB through the intermediate electrode CTE, the read-out line, and the side surface connection line.

The conductive member CAM may attach the flexible printed circuit board FPCB to the intermediate electrode CTE. For example, the conductive member CAM may include an anisotropic conductive film. In case that the conductive member CAM includes the anisotropic conductive film, the conductive member CAM may have conductivity in an area where the intermediate electrode CTE and the flexible printed circuit board FPCB contact, and may electrically connect the flexible printed circuit board FPCB to the intermediate electrode CTE.

As described above, as the flexible printed circuit board FPCB is disposed on the lower surface BSS of the substrate SUB, the non-display area NDA of FIG. 5 may have a reduced area.

FIG. 9 is an enlarged schematic plan view illustrating an area B of FIG. 5. Hereinafter, for convenience of description, embodiments of the disclosure are described based on the area B overlapping q-th and (q+1)-th fan out lines FOLq and FOLq+1. It will be understood that areas overlapped other fan out lines among first to p-th fan out lines FOL1 to FOLp may be described similarly to the area B.

Referring to FIGS. 5 and 9, each of the q-th and (q+1)-th fan out lines FOLq and FOLq+1 may extend in the second direction DR2 or in a direction opposite to the second direction DR2. The q-th and (q+1)-th fan out lines FOLq and FOLq+1 may be arranged along the first direction DR1.

Each of the fan out lines FOLq and FOLq+1 may include one or more first openings OP1 in an area overlapping the side surface connection line. The q-th fan out line FOLq may include multiple holes HLE1 and HLE2 and multiple slits SLT1 and SLT2 as first openings OP1. Multiple holes HLE1 and HLE2 may be disposed between multiple slits SLT1 and SLT2 and the display area DA. The (q+1)-th fan out line FOLq+1 may also include first openings similar to the q-th fan out line FOLq.

Each of the fan out lines FOLq and FOLq+1 may include at least one material among copper (Cu), molybdenum (Mo), tungsten (W), aluminum neodymium (AlNd), titanium (Ti), aluminum (Al), and silver (Ag).

In the non-display area NDA, first and second upper pad electrodes UPD1 and UPD2 respectively covering the q-th and (q+1)-th fan out lines FOLq and FOLq+1 may be provided. Each of the first and second upper pad electrodes UPD1 and UPD2 may include a conductive material suitable for protecting a corresponding fan out line during a manufacturing process. For example, the first and second upper pad electrodes UPD1 and UPD2 may include at least one of transparent conductive materials such as indium tin oxide (ITO), indium zinc oxide (IZO), zinc oxide (ZnOx), indium gallium zinc oxide (IGZO), and indium tin zinc oxide (ITZO).

A second insulating layer ISL2 may be disposed on the first and second upper pad electrodes UPD1 and UPD2. The second insulating layer ISL2 may include a second opening OP2 exposing portions of the first and second upper pad electrodes UPD1 and UPD2.

The q-th fan out line FOLq may include a first row of holes HLE1 and second row of holes HLE2, and the first row of holes HLE1 and the second row of holes HLE2 overlap the second insulating layer ISL2. Each of the first row of holes HLE1 and the second row of holes HLE2 may have a circular shape. As depicted in FIG. 9, the q-th fan out line FOLq is shown as including two rows of holes HLE1 and HLE2, but an arrangement of holes is not limited thereto. For example, the q-th fan out line FOLq may include more rows of holes. In other examples, the holes of the q-th fan out line FOLq may be arranged in a zigzag form.

The q-th fan out line FOLq may include first and second slits SLT1 and SLT2, and the first and second slits SLT1 and SLT2 may overlap the second opening OP2. Each of the first and second slits SLT1 and SLT2 may extend in the first direction DR1, and the first and second slits SLT1 and SLT2 may be arranged in the second direction DR2. Each of the first and second slits SLT1 and SLT2 may have a stripe shape. However, embodiments are not limited thereto. For example, the q-th fan out line FOLq may include one slit or may include three or more slits.

The (q+1)-th fan out line FOLq+1 is similarly configured to the q-th fan out line FOLq. An overlapping description is omitted.

FIG. 10 is a schematic cross-sectional view taken along line II-II′ of FIG. 9 according to an embodiment of the disclosure.

Referring to FIGS. 5, 9, and 10, the first pixel circuit layer PCL1 may be disposed on the upper surface FSS of the substrate SUB, the second pixel circuit layer PCL2 may be disposed on the lower surface BSS of the substrate SUB, and the side surface connection line SCL may be disposed on the side surface SSS of the substrate SUB. The side surface SSS of the substrate SUB may correspond to the first side surface SS1 of FIG. 5.

The first pixel circuit layer PCL1 may include the upper buffer layer UBFL, a first insulating layer ISL1, the q-th fan out line FOLq, the first upper pad electrode UPD1, a second insulating layer ISL2, and a third insulating layer ISL3.

The upper buffer layer UBFL may be disposed on the upper surface FSS of the substrate SUB.

The first insulating layer ISL1 may be disposed on the upper buffer layer UBFL. The first insulating layer ISL1 may be disposed generally in the display area DA and the non-display area NDA. The first insulating layer ISL1 may be one of the interlayer insulating layers ILD of FIG. 8 in the display area DA. However, embodiments are not limited thereto. For example, the first insulating layer ISL1 may be one of the first passivation layer PSV1 or the second passivation layer PSV2 of FIG. 8 in the display area DA.

The q-th fan out line FOLq may be disposed on the first insulating layer ISL1. The q-th fan out line FOLq may be disposed in the same layer as the first and second terminals ET1 and ET2 of FIG. 8. However, embodiments are not limited thereto. The q-th fan out line FOLq may be disposed in the same layer as the connection pattern CP or may be disposed in the same layer as the first anode electrode AE1 and the cathode electrode CE.

The q-th fan out line FOLq may include the first and second holes HLE1 and HLE2 in a portion overlapping the second insulating layer ISL2. The q-th fan out line FOLq may include the first and second slits SLT1 and SLT2 in a portion overlapping the second opening OP2 of the second insulating layer ISL2. The first and second holes HLE1 and HLE2 and the first and second slits SLT1 and SLT2 overlap a side surface connection line SCL.

The first upper pad electrode UPD1 may be disposed on the q-th fan out line FOLq. The first upper pad electrode UPD1 may cover a portion of the q-th fan out line FOLq adjacent to the side surface SSS of the substrate SUB.

The first upper pad electrode UPD1 may be directly disposed on the q-th fan out line FOLq. Accordingly, the first upper pad electrode UPD1 may have a first groove GRV11, a second groove GRV12, a third groove GRV13, and a fourth groove GRV14 respectively overlapping the first hole HLE1, the second hole HLE2, the first slit SLT1, and the second slit SLT2 in the third direction DR3 (e.g., thickness direction). Since the first upper pad electrode UPD1 is directly disposed on the q-th fan out line FOLq, in a plan view, the first to fourth grooves GRV11 to GRV14 may respectively have the same shapes as the first hole HLE1, the second hole HLE2, the first slit SLT1, and the second slit SLT2.

The second insulating layer ISL2 may be disposed on the first upper pad electrode UPD1. The second insulating layer ISL2 may include the second opening OP2 exposing a portion of the first upper pad electrode UPD1, as described with reference to FIG. 9. Due to the second opening OP2, the second insulating layer ISL2 may overlap the first and second holes HLE1 and HLE2 without overlapping the first and second slits SLT1 and SLT2. The third and fourth grooves GRV13 and GRV14 of the first upper pad electrode UPD1 may contact the side surface connection line SCL.

The second insulating layer ISL2 may be directly disposed on the first upper pad electrode UPD1 in the non-display area NDA. Accordingly, the second insulating layer ISL2 may have fifth and sixth grooves GRV21 and GRV22 respectively overlapping the first and second grooves GRV11 and GRV12. In a plan view, the fifth and sixth grooves GRV21 and GRV22 may respectively have the same shapes as the first and second grooves GRV11 and GRV12. The fifth and sixth grooves GRV21 and GRV22 of the second insulating layer ISL2 may contact the side surface connection line SCL.

The second insulating layer ISL2 may be disposed generally in the display area DA and the non-display area NDA. The second insulating layer ISL2 may be the first passivation layer PSV1 of FIG. 8 in the display area DA. However, embodiments are not limited thereto in case that the second insulating layer ISL2 is directly disposed on the first upper pad electrode UPD1. For example, the second insulating layer ISL2 may be the second passivation layer PSV2 in the display area DA.

The third insulating layer ISL3 may be disposed on the second insulating layer ISL2. The third insulating layer ISL3 may be disposed generally in the display area DA and the non-display area NDA. The third insulating layer ISL3 may be the second passivation layer PSV2 of FIG. 8 in the display area DA. However, embodiments are not limited thereto. For example, the third insulating layer ISL3 may be an inorganic insulating layer or an organic insulating layer additionally disposed on the second passivation layer PSV2 in the display area DA.

The second pixel circuit layer PCL2 may include the lower buffer layer LBFL, the read-out line LOL, the lower pad electrode LPD, and the fourth insulating layer ISL4.

The lower buffer layer LBFL may be disposed on the lower surface BSS of the substrate SUB.

The read-out line LOL may be disposed on the lower buffer layer LBFL. The read-out line LOL may be electrically connected to the intermediate electrode CTE of FIG. 8. The read-out line LOL may be electrically connected to the flexible printed circuit board FPCB of FIG. 8 through the intermediate electrode CTE. The read-out line LOL may be disposed in the same layer as the intermediate electrode CTE. The read-out line LOL may include the same material as the q-th fan out line FOLq. For example, the read-out line LOL may include at least one material among copper (Cu), molybdenum (Mo), tungsten (W), aluminum neodymium (AlNd), titanium (Ti), aluminum (Al), and silver (Ag).

The lower pad electrode LPD may be disposed on the read-out line LOL. The lower pad electrode LPD may cover a portion of the read-out line LOL adjacent to the side surface SSS of the substrate SUB. The lower pad electrode LPD may include a conductive material suitable for protecting the read-out line LOL during the manufacturing process. For example, the lower pad electrode LPD may include the same material as the first upper pad electrode UPD1.

The fourth insulating layer ISL4 may be disposed on the lower pad electrode LPD. The fourth insulating layer ISL4 may include a third opening OP3 exposing a portion of the lower pad electrode LPD.

The fourth insulating layer ISL4 may be disposed generally in the display area DA and the non-display area NDA. The fourth insulating layer ISL4 may be the third passivation layer PSV3 of FIG. 8 in the display area DA.

The side surface connection line SCL may be disposed on the side surface SSS of the substrate SUB. The side surface connection line SCL may be further extended and disposed on the upper surface FSS and the lower surface BSS of the substrate SUB.

The side surface connection line SCL may be disposed on the first upper pad electrode UPD1 and the second insulating layer ISL2. The side surface connection line SCL may overlap the first openings OP1. The side surface connection line SCL may contact a portion of the first upper pad electrode UPD1 exposed by the second opening OP2. Accordingly, the side surface connection line SCL may be electrically connected to the q-th fan out line FOLq through the first upper pad electrode UPD1. The side surface connection line SCL may be disposed on the lower pad electrode LPD and the fourth insulating layer ISL4. The side surface connection line SCL may contact a portion of the lower pad electrode LPD exposed by the third opening OP3. Accordingly, the side surface connection line SCL may be electrically connected to the read-out line LOL through the lower pad electrode LPD. Therefore, the side surface connection line SCL may electrically connect the q-th fan out line FOLq to the read-out line LOL. As a result, the voltage or the signal from the flexible printed circuit board FPCB of FIG. 8 may be transmitted to the q-th fan out line FOLq through the read-out line LOL, the lower pad electrode LPD, the side surface connection line SCL, and the first upper pad electrode UPD1.

The third and fourth grooves GRV13, GRV14 may be formed in a portion of the first upper pad electrode UPD1 contacting the side surface connection line SCL, and the fifth and sixth grooves GRV21 and GRV22 may be formed in the second insulating layer ISL2 contacting the side surface connection line SCL. As the side surface connection line SCL contacts the third to sixth grooves GRV13, GRV14, GRV21, and GRV22, a cross-section of the side surface connection line SCL may have shapes respectively complementary to the third to sixth grooves GRV13, GRV14, GRV21, and GRV22. As described above, the complementary shapes of the side surface connection line SCL and the third to sixth grooves GRV13, GRV14, GRV21, and GRV22 may be engaged with each other.

During the manufacturing process, various stresses may be applied to the display panel DP from an outside, and in particular, relatively more stress may be applied to the first to fourth side surfaces SS1 to SS4 of the display panel DP (refer to FIG. 5). For example, in some manufacturing steps, a portion of the display panel DP may be manufactured, a portion of the manufactured display panel DP may be transported on a carrier, and in another portion of the display panel DP may be manufactured in next manufacturing steps. During a transportation process, shock may be applied to the display panel DP, and more shock may be applied to an edge portion of the display panel DP. Due to such a stress, a defect may occur in the side surface connection line SCL disposed on at least one of the first to fourth side surfaces SS1 to SS4 of the display panel DP (refer to FIG. 5). For example, a portion of the side surface connection line SCL may be lost or deformed due to stress.

The side surface connection line SCL may engage with the third to sixth grooves GRV13, GRV14, GRV21, and GRV22. Accordingly, the side surface connection line SCL may be relatively firmly fixed to the first pixel circuit layer PCL1 and the substrate SUB. Therefore, loss or deformation of the side surface connection line SCL due to stress during the manufacturing process may be prevented, and thus the side surface connection line SCL and the display panel DP having improved reliability may be provided.

Since a portion of the first upper pad electrode UPD1 overlapping the second opening OP2 includes the third and fourth grooves GRV13 and GRV14 having shapes similar to those of the first and second slits SLT1 and SLT2, the portion may have relatively high step coverage compared to another portion of the first upper pad electrode UPD1 including the first and second grooves GRV11 and GRV12. For example, in an area overlapping the second opening OP2, the first upper pad electrode UPD1 may have a relatively uniform thickness even though the first upper pad electrode UPD1 includes the third and fourth grooves GRV13 and GRV14. Accordingly, the portion of the first upper pad electrode UPD1 overlapping the second opening OP2 may have high reliability, and thus the side surface connection line SCL may be electrically connected to the q-th fan out line FOLq with high reliability.

Since the second insulating layer ISL2 includes the fifth and sixth grooves GRV21 and GRV22 having shapes similar to those of the first and second holes HLE1 and HLE2, the second insulating layer ISL2 may be relatively firmly engaged with the side surface connection line SCL compared to the third and fourth grooves GRV13 and GRV14. The number of first and second holes HLE1 and HLE2 may increase. Therefore, the side surface connection line SCL may be further prevented from being lost or deformed due to stress during the manufacturing process.

FIG. 11 is a schematic cross-sectional view taken along line II-II′ of FIG. 9 according to another embodiment of the disclosure.

Referring to FIGS. 5, 9, and 11, the first pixel circuit layer PCL1 may be disposed on the upper surface FSS of the substrate SUB, a second pixel circuit layer PCL2′ may be disposed on the lower surface BSS of the substrate SUB, and a side surface connection line SCL′ may be disposed on the side surface SSS of the substrate SUB.

The first pixel circuit layer PCL1 is similarly configured to the first pixel circuit layer PCL1 of FIG. 10. Hereinafter, an overlapping description is omitted.

The second pixel circuit layer PCL2′ may include the lower buffer layer LBFL, a read-out line LOL′, a lower pad electrode LPD′, and a fourth insulating layer ISL4′.

The read-out line LOL′ may be disposed on the lower buffer layer LBFL. The read-out line LOL′ may be electrically connected to the intermediate electrode CTE of FIG. 8.

The read-out line LOL′ may include fourth openings OP4 in an area overlapping the side surface connection line SCL′. Similarly to the q-th fan out line FOLq, the read-out line LOL′ may include third and fourth holes HLE3, HLE4 in a portion overlapping the fourth insulating layer ISL4′, and may include third and fourth slits SLT3 and SLT4 in a portion overlapping the third opening OP3 of the fourth insulating layer ISL4′. The third and fourth holes HLE3 and HLE4 and the third and fourth slits SLT3 and SLT4 may be included in the fourth openings OP4.

The third and fourth holes HLE3, HLE4 may respectively overlap the first and second holes HLE1 and HLE2 in the third direction DR3 (e.g., thickness direction), and the third and fourth slits SLT3, SLT4 may respectively overlap the first and second slits SLT1 and SLT2 in the third direction DR3 (e.g., thickness direction).

The lower pad electrode LPD′ may be disposed on the read-out line LOL′. The lower pad electrode LPD′ may cover a portion of the read-out line LOL′ adjacent to the side surface SSS of the substrate SUB.

The lower pad electrode LPD′ may be directly disposed on the read-out line LOL′. Accordingly, the lower pad electrode LPD′ may have a seventh groove GRV31, an eighth groove GRV32, a ninth groove GRV33, and a tenth groove GRV34 respectively overlapping the third hole HLE3, the fourth hole HLE4, the third slit SLT3, and the fourth slit SLT4 in the third direction DR3 (e.g., thickness direction). In a plan view, the seventh to tenth grooves GRV31 to GRV34 may respectively have the same shapes as the third hole HLE3, the fourth hole HLE4, the third slit SLT3, and the fourth slit SLT4. The ninth and tenth grooves GRV33 and GRV34 of the lower pad electrode LPD′ may contact the side surface connection line SCL′.

The fourth insulating layer ISL4′ may be disposed on the lower pad electrode LPD′. The fourth insulating layer ISL4′ may include a third opening OP3 exposing a portion of the lower pad electrode LPD′. Due to the third opening OP3, the fourth insulating layer ISL4′ may overlap the third and fourth holes HLE3 and HLE4 without overlapping the third and fourth slits SLT3 and SLT4 in the third direction DR3 (e.g., thickness direction).

The fourth insulating layer ISL4′ may be directly disposed on the lower pad electrode LPD′. Accordingly, the fourth insulating layer ISL4′ may have eleventh and twelfth grooves GRV41 and GRV42 respectively overlapping the seventh and eighth grooves GRV31 and GRV32 in the third direction DR3 (e.g., thickness direction). In a plan view, the eleventh and twelfth grooves GRV41 and GRV42 may respectively have the same shapes as the seventh and eighth grooves GRV32 and GRV31. The eleventh and twelfth grooves GRV41 and GRV42 of the fourth insulating layer ISL4′ may contact the side surface connection line SCL′.

The side surface connection line SCL′ may be disposed on the lower pad electrode LPD′ and the fourth insulating layer ISL4′. The side surface connection line SCL′ may overlap the fourth openings OP4. The side surface connection line SCL′ may contact a portion of the lower pad electrode LPD′ exposed by the third opening OP3. Accordingly, the side surface connection line SCL′ may electrically connect the q-th fan out line FOLq to the read-out line LOL′.

As the side surface connection line SCL′ contacts the ninth to twelfth grooves GRV33, GRV34, GRV41, GRV42, a cross-section of the side surface connection line SCL′ may respectively have shapes complementary to the ninth to twelfth grooves GRV33, GRV34, GRV41, and GRV42. As described above, the complementary shapes of the side surface connection line SCL′ and the ninth to twelfth grooves GRV33, GRV34, GRV41, and GRV42 may be engaged with each other. Therefore, the side surface connection line SCL′ may be relatively firmly fixed not only to the first pixel circuit layer PCL1 but also to the second pixel circuit layer PCL2. Therefore, loss or deformation of the side surface connection line SCL′ due to stress during the manufacturing process may be further prevented.

FIG. 12 is an enlarged schematic plan view of the area B of the lower surface of the display panel of FIG. 5 viewed in the third direction. Line II-II′ of FIG. 12 may be the same cross-sectional line as line II-II′ of FIG. 9, and thus FIG. 11 may be understood as a schematic cross-sectional view taken along line II-II′ of FIG. 12. A q-th read-out line LOLq of FIG. 12 may be the read-out line LOL′ of FIG. 11, and a first lower pad electrode LPD1 of FIG. 12 may be the lower pad electrode LPD′ of FIG. 11.

Referring to FIG. 12, the q-th read-out line LOLq and a (q+1)-th read-out line LOLq+1 are provided. Each of the q-th and (q+1)-th read-out lines LOLq and LOLq+1 may extend in the second direction DR2 or in the direction opposite to the second direction DR2. The q-th and (q+1)-th read-out lines LOLq and LOLq+1 may be arranged along the first direction DR1.

The q-th and (q+1)-th read-out lines LOLq and LOLq+1 may be similarly configured to the q-th and (q+1)-th fan out lines FOLq and FOLq+1 of FIG. 9. Each of the read-out lines LOLq and LOLq+1 may include fourth openings OP4 overlapping the side surface connection line SCL′ of FIG. 11. The q-th read-out line LOLq may include multiple holes HLE3 and HLE4 and multiple slits SLT3 and SLT4 as the fourth openings OP4. Similarly to the q-th fan out line FOLq, the (q+1)-th fan out line FOLq+1 may also include multiple holes and multiple slits.

In the non-display area NDA, first and second lower pad electrodes LPD1 and LPD2 respectively covering the q-th and (q+1)-th read-out lines LOLq and LOLq+1 may be provided.

The fourth insulating layer ISL4′ may be disposed on the first and second lower pad electrodes LPD1 and LPD2. The fourth insulating layer ISL4′ may include a third opening OP3 exposing portions of the first and second lower pad electrodes LPD1 and LPD2.

In an area overlapping the fourth insulating layer ISL4′, the q-th read-out line LOLq may include a third row of holes HLE3 and a fourth row of holes HLE4. As depicted in FIG. 12, the q-th read-out line LOLq is shown as including two rows of holes, but embodiments are not limited thereto. For example, the q-th read-out line LOLq may include more rows of holes. In other examples, holes of the q-th fan out line FOLq may be arranged in a zigzag form. Due to multiple holes HLE3 and HLE4, the side surface connection line SCL′ may be relatively firmly engaged with the fourth insulating layer ISL4′.

In an area overlapping the third opening OP3 of the fourth insulating layer ISL4′, the q-th read-out line LOLq may include the third and fourth slits SLT3 and SLT4. Each of the third and fourth slits SLT3 and SLT4 may extend in the first direction DR1, and the third and fourth slits SLT3 and SLT4 may be arranged in the second direction DR2. However, embodiments are not limited thereto. For example, the q-th read-out line LOLq may include one slit or may include three or more slits. Due to these third and fourth slits SLT3 and SLT4, the first lower pad electrode LPD1 may have relatively high step coverage even though the first lower pad electrode LPD1 includes the ninth and tenth grooves GRV33 and GRV34. Accordingly, a portion of the first lower pad electrode LPD1 overlapping the third opening OP3 may have high reliability, and thus the side surface connection line SCL′ may be electrically connected to the q-th read-out line LOLq with high reliability.

The (q+1)-th read-out line LOLq+1 is similarly configured to the q-th read-out line LOLq. An overlapping description is omitted.

The q-th read-out line LOLq may be electrically connected to the q-th fan out line FOLq of FIG. 9 through the side surface connection line SCL′ of FIG. 11. Similarly, the (q+1)-th read-out line LOLq+1 may be electrically connected to the (q+1)-th fan out line FOLq+1 of FIG. 9 through another side surface connection line.

FIGS. 13 to 21 are schematic cross-sectional views illustrating a method of manufacturing a display panel according to the embodiment of FIG. 11.

Referring to FIG. 13, after disposing the substrate SUB so that the upper surface FSS of the substrate SUB faces upward, the upper buffer layer UBFL and the first insulating layer ISL1 may be sequentially formed on the upper surface FSS of the substrate SUB.

The first insulating layer ISL1 may be formed generally in the display area DA (refer to FIG. 5) and the non-display area NDA (refer to FIG. 5), and may be provided as one of the interlayer insulating layers ILD of FIG. 8 in the display area DA. However, embodiments are not limited thereto. For example, the first insulating layer ISL1 may be provided as one the first passivation layer PSV1 or the second passivation layer PSV2 of FIG. 8 in the display area DA.

A first metal layer ML1 may be formed on the first insulating layer ISL1. The first metal layer ML1 may include at least one material among copper (Cu), molybdenum (Mo), tungsten (W), aluminum neodymium (AlNd), titanium (Ti), aluminum (Al), and silver (Ag).

Referring to FIG. 14, by etching portions of the first metal layer ML1 in the non-display area NDA, the q-th fan out line FOLq having the first and second holes HLE1 and HLE2 and the first and second slits SLT1 and SLT2 may be formed. Conductive patterns of the display area DA positioned in the same layer as the q-th fan out line FOLq may be formed by etching portions of the first metal layer ML1 in the display area DA. For example, in case that the q-th fan out line FOLq is formed in the non-display area NDA, the first and second terminals ET1 and ET2 of FIG. 8 may be formed in the display area DA. However, embodiments are not limited thereto. In case that the q-th fan out line FOLq is formed in the non-display area NDA, the first anode electrode AE1 and the cathode electrode CE may be formed in the display area DA.

Referring to FIG. 15, the first upper pad electrode UPD1 may be formed on the q-th fan out line FOLq. As the first upper pad electrode UPD1 is directly formed on the q-th fan out line FOLq, the first upper pad electrode UPD1 may include the first to fourth grooves GRV11 to GRV14 corresponding to the first and second holes HLE1 and HLE2 and the first and second slits SLT1 and SLT2. In a plan view, the first to fourth grooves GRV11 to GRV14 may respectively have the same shapes as the first and second holes HLE1 and HLE2 and the first and second slits SLT1 and SLT2.

Referring to FIG. 16, the second insulating layer ISL2 may be formed on the q-th fan out line FOLq. The second insulating layer ISL2 may have the second opening OP2 overlapping the first and second slits SLT1 and SLT2. As the second insulating layer ISL2 is directly formed on the first upper pad electrode UPD1, the second insulating layer ISL2 may have the fifth and sixth grooves GRV21 and GRV22. In a plan view, the fifth and sixth grooves GRV21 and GRV22 may respectively have the same shapes as the first and second holes HLE1 and HLE2.

The second insulating layer ISL2 may be generally formed in the display area DA and the non-display area NDA, and may be provided as the first passivation layer PSV1 of FIG. 8 in the display area DA. However, embodiments are not limited thereto. For example, the second insulating layer ISL2 may be provided as the second passivation layer PSV2 in the display area DA.

Thereafter, the third insulating layer ISL3 may be formed on the second insulating layer ISL2.

Referring to FIG. 17, after flipping the substrate SUB upside down so that the lower surface BSS of the substrate SUB faces upward, and the upper surface FSS of the substrate faces downward, the lower buffer layer LBFL may be formed on the substrate SUB.

A second metal layer ML2 may be formed on the lower buffer layer LBFL. The second metal layer ML2 may include at least one material among copper (Cu), molybdenum (Mo), tungsten (W), aluminum neodymium (AlNd), titanium (Ti), aluminum (AI), and silver (Ag).

Referring to FIG. 18, in the non-display area NDA, by etching portions of the second metal layer ML2, the read-out line LOL′ having the third and fourth holes HLE3 and HLE4 and the third and fourth slits SLT3 and SLT4 may be formed.

Referring to FIG. 19, the lower pad electrode LPD′ may be formed on the read-out line LOL′. As the lower pad electrode LPD′ is directly formed on the read-out line LOL′, the lower pad electrode LPD′ may include the seventh to tenth grooves GRV31 to GRV34 corresponding to the third and fourth holes HLE3 and HLE4 and the third and fourth slits SLT3 and SLT4. In a plan view, the seventh to tenth grooves GRV31 to GRV34 may respectively have the same shapes as the third and fourth holes HLE3 and HLE4 and the third and fourth slits SLT3 and SLT4.

Referring to FIG. 20, the fourth insulating layer ISL4′ may be formed on the read-out line LOL′. The fourth insulating layer ISL4′ may have the third opening OP3 overlapping the third and fourth slits SLT3 and SLT4. As the fourth insulating layer ISL4′ is directly formed on the read-out line LOL′, the fourth insulating layer ISL4′ may have eleventh and twelfth grooves GRV41 and GRV42. In a plan view, the eleventh and twelfth grooves GRV41 and GRV42 may respectively have the same shapes as the third and fourth holes HLE3 and HLE4.

Referring to FIG. 21, after flipping the substrate SUB upside down so that the upper surface FSS of the substrate SUB faces upward, and the lower surface BSS of the substrate SUB faces downward, the side surface SSS of the substrate SUB may be processed to have a rounded shape. For example, chamfer processing may be performed on the side surface SSS of the substrate SUB. The rounded shape of the side surface SSS of the substrate SUB allows the side surface connection line SCL′ of FIG. 11 to be efficiently and effectively fixed to the side surface SSS of the substrate SUB.

Subsequently, a side surface connection line SCL′ electrically connected to a portion of the first upper pad electrode UPD1 exposed by the second opening OP2 and a portion of the lower pad electrode LPD′ exposed by the third opening OP3 may be formed as shown in FIG. 11. In the first pixel circuit layer PCL1, the side surface connection line SCL′ may be engaged with the third to sixth grooves GRV13, GRV14, GRV21, and GRV22. In the second pixel circuit layer PCL2, the side surface connection line SCL′ may be engaged with the ninth to twelfth grooves GRV33, GRV34, GRV41, and GRV42. Accordingly, the side surface connection line SCL′ may be relatively firmly fixed to the substrate SUB, the first pixel circuit layer PCL1, and the second pixel circuit layer PCL2′. Therefore, loss or deformation of the side surface connection line SCL′ due to stress during the manufacturing process may be prevented, and thus the side surface connection line SCL′ and the display panel DP having improved reliability may be provided.

FIG. 22 is a schematic block diagram illustrating an embodiment of a display system.

Referring to FIG. 22, the display system 1000 may include a processor 1100 and a display device 1200.

The processor 1100 may perform various tasks and calculations. The processor 1100 may include an application processor, a graphics processor, a microprocessor, a central processing unit (CPU), and the like. The processor 1100 may be electrically connected to other components of the display system 1000 through a bus system to control the other components.

The processor 1100 may transmit image data IMG and a control signal CTRL to the display device 1200. The display device 1200 may display an image based on the image data IMG and the control signal CTRL. The display device 1200 may be similarly configured to the display device DD described with reference to FIG. 1. For example, the image data IMG and the control signal CTRL may be provided as the input image data IMG and the control signal CTRL of FIG. 1, respectively.

The display system 1000 may include a computing system providing an image display function, such as a smart watch, a mobile phone, a smart phone, a portable computer, a tablet personal computer (PC), a watch phone, an automotive display, smart glasses, a portable multimedia player (PMP), a navigation device, and an ultra mobile personal computer (UMPC). The display system 1000 may include at least one of a head mounted display (HMD) device, a virtual reality (VR) device, a mixed reality (MR) device, and an augmented reality (AR) device.

FIGS. 23 to 26 are schematic perspective views illustrating application examples of the display system of FIG. 22.

Referring to FIG. 23, the display system 1000 of FIG. 22 may be applied to a smart watch 2000 including a display unit 2100 and a strap unit 2200.

The smart watch 2000 may be a wearable electronic device. For example, the smart watch 2000 may have a structure in which the strap unit 2200 is mounted on a user's wrist. Here, the display system 1000 and/or the display device 1200 may be applied to the display unit 2100, and image data including time information may be provided to a user.

Referring to FIG. 24, the display system 1000 of FIG. 22 may be applied to an automotive display system 3000. The automotive display system 3000 may include a computing system provided inside and/or outside a vehicle to provide image data.

For example, the display system 1000 and/or the display device 1200 may be applied to at least one of an infotainment panel 3100, a cluster 3200, a co-driver display 3300, a head-up display 3400, a side mirror display 3500, and a rear seat displays 3600 provided in a vehicle.

Referring to FIG. 25, the display system 1000 of FIG. 22 may be applied to smart glasses 4000. The smart glasses 4000 may be a wearable electronic device that may be worn on a user's head. For example, the smart glasses 4000 may be a wearable device for augmented reality.

The smart glasses 4000 may include a frame 4100 and a lens unit 4200. The frame 4100 may include a housing 4110 that supports the lens unit 4200 and a leg unit 4120 for the user to wear. The leg unit 4120 may be electrically connected to the housing 4110 through a hinge and may be folded or unfolded relative to the housing 4110.

A battery, a touch pad, a microphone, a camera, and the like may be built in the frame 4100. A projector that outputs light, a processor that controls a light signal, and the like may be built in the frame 4100.

The lens unit 4200 may include an optical member that transmits or reflects light. For example, the lens unit 4200 may include glass, transparent synthetic resin, or the like.

In order for user's eyes to recognize visual information, the lens unit 4200 may reflect an image by the light signal transmitted from the projector of the frame 4100 by a rear surface (for example, a surface of a direction facing the user's eyes) of the lens unit 4200. For example, the user may recognize visual information such as time and date displayed on the lens unit 4200. At this time, the projector and/or the lens unit 4200 may be a type of display device. The display device 1200 may be applied to the projector and/or the lens unit 4200.

Referring to FIG. 26, the display system 1000 of FIG. 22 may be applied to a head mounted display device 5000.

The head mounted display device 5000 may be a wearable electronic device that may be worn on a user's head. For example, the head mounted display device 5000 may be a wearable device for virtual reality or mixed reality.

The head mounted display device 5000 may include a head mount band 5100 and a display device receiving case 5200. The head mount band 5100 may be connected to the display device receiving case 5200. The head mount band 5100 may include a horizontal band and/or a vertical band for fixing the head mounted display device 5000 to a user's head. The horizontal band may surround a side portion of the user's head, and the vertical band may surround an upper portion of the user's head. However, embodiments are not limited thereto. For example, the head mount band 5100 may be implemented in a form of a glasses frame, a helmet, or the like.

The display device receiving case 5200 may receive the display system 1000 and/or the display device 1200.

In other embodiments, the display system 1000 shown in FIG. 22 may be applied to, a mobile phone, a smartphone, a portable computer, a tablet personal computer (PC), a watch phone, a portable multimedia player (PMP), a navigation system, an ultra-mobile computer (UMPC), a virtual reality (VR) device, a mixed reality (MR) device, and an augmented reality (AR) device.

Although specific embodiments and application examples are described herein, other embodiments and modifications may be derived from the above description. Therefore, the spirit of the disclosure is not limited to such embodiments, and extends to the scope of the claims set forth below, various obvious modifications, and equivalents.

What is claimed is:

1. A display device comprising:
a substrate having an upper surface, a lower surface opposite to the upper surface, and a side surface connecting the upper surface and the lower surface;
a light emitting element disposed on the upper surface of the substrate in a display area;
an upper conductive line disposed on the upper surface of the substrate in a non-display area around the display area and having first openings;
an upper pad electrode disposed on the upper conductive line;
a first insulating layer disposed on the upper pad electrode and exposing a portion of the upper pad electrode;
a lower conductive line disposed on the lower surface of the substrate in the non-display area; and
a side surface connection line disposed on the side surface of the substrate, electrically connecting the exposed portion of the upper pad electrode to the lower conductive line, and overlapping the first openings,
wherein the upper pad electrode has first grooves overlapping the first openings in a thickness direction.

2. The display device of claim 1, wherein the first insulating layer has second grooves overlapping a portion of the first grooves.

3. The display device of claim 2, wherein
the first grooves have substantially the same shape as the first openings in a plan view, and
the second grooves have substantially the same shape as the portion of the first grooves in a plan view.

4. The display device of claim 1, wherein
the upper pad electrode is disposed on the upper conductive line and is in direct contact with the upper conductive line, and
the first insulating layer is disposed on the upper pad electrode and is in direct contact with the upper pad electrode.

5. The display device of claim 1, wherein
the first openings include one or more holes adjacent to each other and one or more slits adjacent to each other, and
the first insulating layer overlaps the one or more holes without overlapping the one or more slits.

6. The display device of claim 5, wherein
the non-display area is adjacent to the display area in a first direction, and
the one or more slits extend in a second direction crossing the first direction.

7. The display device of claim 5, wherein in a plan view, each of the one or more holes has a circular shape, and each of the one or more slits has a stripe shape.

8. The display device of claim 5, wherein the one or more holes are disposed between the one or more slits and the display area.

9. The display device of claim 1, further comprising:
a second insulating layer disposed on the upper surface of the substrate in the display area and the non-display area, wherein
in the non-display area, the upper conductive line is disposed on the second insulating layer, and
in the display area, the light emitting element is disposed on the second insulating layer.

10. The display device of claim 1, further comprising:
a lower pad electrode disposed on the lower conductive line; and
a second insulating layer disposed on the lower pad electrode and exposing a portion of the lower pad electrode,
wherein the side surface connection line is electrically connected to the exposed portion of the upper pad electrode and the exposed portion of the lower pad electrode.

11. The display device of claim 10, wherein the lower conductive line has second openings, and
the side surface connection line overlaps the second openings.

12. The display device of claim 11, wherein
the lower pad electrode has second grooves overlapping the second openings, and
the second insulating layer has third grooves overlapping a portion of the second grooves.

13. The display device of claim 11, wherein
the lower pad electrode is disposed on the lower conductive line and is in direct contact with the lower conductive line, and
the second insulating layer is disposed on the lower pad electrode and is in direct contact with the lower pad electrode.

14. The display device of claim 11, wherein the second openings overlap the first openings.

15. A method of manufacturing a display device, the method comprising:
forming a metal layer on an upper surface of a substrate in a non-display area around a display area;
forming an upper conductive line having first openings by removing portions of the metal layer;
forming an upper pad electrode on the upper conductive line;
forming a first insulating layer exposing a portion of the upper pad electrode, on the upper pad electrode;
forming a lower conductive line on a lower surface opposite to the upper surface of the substrate in the non-display area; and
forming a side surface connection line on a side surface connecting the upper surface and the lower surface of the substrate to electrically connect the exposed portion of the upper pad electrode to the lower conductive line,
wherein the upper pad electrode has first grooves overlapping the first openings in a thickness direction.

16. The method of claim 15, wherein the first insulating layer has second grooves overlapping a portion of the first grooves.

17. The method of claim 15, further comprising:
forming a lower pad electrode on the lower conductive line; and
forming a second insulating layer exposing a portion of the lower pad electrode, on the lower pad electrode,
wherein the side surface connection line is electrically connected to the exposed portion of the upper pad electrode and the exposed portion of the lower pad electrode.

18. The method of claim 17, wherein
the lower conductive line has second openings,
the lower pad electrode has second grooves overlapping the second openings, and
the second insulating layer has third grooves overlapping a portion of the second grooves.

19. An electronic device comprising:
a display device to display images based on image data, wherein
the display device includes:
a substrate having an upper surface, a lower surface opposite to the upper surface, and a side surface connecting the upper surface and the lower surface;
a light emitting element disposed on the upper surface of the substrate in a display area;
an upper conductive line disposed on the upper surface of the substrate in a non-display area around the display area and having first openings;
an upper pad electrode disposed on the upper conductive line;
a first insulating layer disposed on the upper pad electrode and exposing a portion of the upper pad electrode;
a lower conductive line disposed on the lower surface of the substrate in the non-display area; and
a side surface connection line disposed on the side surface of the substrate, electrically connecting the exposed portion of the upper pad electrode to the lower conductive line, and overlapping the first openings, and
the upper pad electrode has first grooves overlapping the first openings in a thickness direction.

20. The electronic device of claim 19, wherein the electronic device is at least one of a smart watch, a mobile phone, a smartphone, a portable computer, a tablet personal computer (PC), a watch phone, an automotive display, a smart glass, a portable multimedia player (PMP), a navigation system, an ultra-mobile computer (UMPC), a head mounted display (HMD) device, a virtual reality (VR) device, a mixed reality (MR) device, and an augmented reality (AR) device.
